(19) United States
(12) Patent Application Publication
(10) Pub. No.: US 2025/0224542 A1
(43) Pub. Date: Jul. 10, 2025

(54) LARGE-SCALE, MASS-PRODUCIBLE, HIGH EFFICIENCY METALENSES

(71) Applicant: The Penn State Research Foundation, University Park, PA (US)

(72) Inventors: Xingjie Ni, University Park, PA (US); Lidan Zhang, University Park, PA (US); Shengyuan Chang, University Park, PA (US)

(21) Appl. No.: 18/854,705

(22) PCT Filed: May 23, 2023
(86) PCT No.: PCT/US2023/023199

§ 371 Date: Oct. 7, 2024

Related U.S. Application Data
(60) Provisional application No. 63/345,153, filed on May 24, 2022.

(51) Int. Cl. G02B 1/00; G02B 1/11; G02B 3/00; G03F 7/00

(52) U.S. Cl. CPC G02B 1/002; G02B 1/11; G02B 3/0018; G03F 7/0005; G02B 2207/101

(57) ABSTRACT

Embodiments relate to a high-efficiency, refractive metalens capable of observing celestial bodies such as the moon. The metalens comprises a plurality of nanocylinders spatially arranged on a substrate, wherein the plurality of nanocylinders provide the metalens with an aperture having a diameter of 80 mm. The metalens is fabricated with deep-ultraviolet (DUV) projection stepper lithography, which is commonly used in the semiconductor industry. Embodiments further relate to a multi-level-compensated metalens (MLCM) that can achieve achromatic focusing and imaging across the entire visible light spectrum (e.g., 400 nm to 700 nm). The MLCM includes nanocylinders made of high-refractive-index silicon nitride and a plurality of stairs made of low-dispersion silicon nitride, separated by a spacer layer.

### CROSS-REFERENCE TO RELATED APPLICATIONS

This application claims priority to U.S. Provisional Patent Application No. 63/345,153, which was filed on May 24, 2022. The entirety of this application is incorporated by reference herein.

### STATEMENT REGARDING FEDERALLY SPONSORED RESEARCH

This invention was made with government support under Contract No. 80GSFC20C0044 awarded by the National Aeronautics & Space Administration. The Government has certain rights in the invention.

### FIELD OF THE INVENTION

Embodiments relate to a large-scale metalens—an artificially engineered subwavelength nanostructure with an ultrathin thickness used to focus light.

### BACKGROUND OF THE INVENTION

Not long after its first appearance, the telescope found its place in astronomy and became the sail to reach for the stars ever since. To this day, humans have constructed telescopic systems that are both land-based and space-borne, revealing valuable insights into the galaxy and the universe. However, the resolving power of telescopes heavily relies on their aperture size, leading to the extreme weight and footprint that bring challenges to their construction and deployment. Similar problems also occur for conventional optical systems relying on complicated multi-element designs to achieve the desired level of optical performance, where elements made of glasses or other refractive materials are bulky and heavy. Moreover, these elements are often cascaded together for aberration correction, leading to a precipitous increase in the size and weight of the system. The solution to these problems may surf with recent advances in nanofabrication techniques and the so-called “metasurfaces”—artificial interfaces that mold light with spatially varying subwavelength nanoantennas, i.e., meta-atoms. Being ultrathin and lightweight, metasurfaces have provided a new approach to recasting optical components into flat devices without performance deterioration. In particular, metasurface lenses, a.k.a. metalenses, have attracted tremendous attention in the past decade for their ultra-thin planar configurations, which promise a drastic reduction in optical systems' size and weight. In addition, metalenses could realize dispersion engineering from chromatic and angular perspectives, which can be utilized to design optical devices ranging from chromatic-aberration-corrected singlets to dispersion-enhanced metalenses for hyperspectral imaging. However, despite the numerous advantages mentioned above, the application of metalenses, or meta-optical devices in general, remains elusive due to their limited aperture sizes.

A major reason for this limit lies in the manufacturing processes of meta-optical devices. Currently, electron-beam (e-beam) lithography and focused ion beam (FIB) are commonly used to define the subwavelength-scale meta-atoms, thanks to their power to resolve nanometer-scale features with high precision. However, being scanning-based techniques, e-beam lithography and FIB come with slow speed, high expense, and limited scalability, making it challenging to fabricate large-aperture meta-optical devices even for mere prototyping, let alone mass production. To date, most of the metalenses reported have only (sub-) millimeter scale apertures. In contrast, conventional lenses with at least centimeter-scale apertures are commonly seen in daily life, even considered entry-level for applications like telescopic imaging. This also implies that if the metasurface can be made with a large aperture and high efficiency, it will become a game-changer in areas previously considered inaccessible to meta-optics, such as planetary observation and remote sensing and imaging.

Over the past years, several attempts have been made to develop cost-effective and scalable fabrication techniques for manufacturing large aperture metalenses. For example, the nano-imprint method has been used to fabricate gallium nitride metalenses with an aperture size of ˜1 cm. Although the nano-imprint technology is mass-production friendly, it suffers from pattern defects, low throughput, and template wear. An alternative method for large-scale metalens fabrication is photolithography, which is known for its superior throughput. Using stepper lithography, metalenses with aperture sizes up to 2 cm have been demonstrated in near-infrared and visible wavelengths. However, those metalenses are still way smaller than their conventional counterparts.

Accordingly, there is a need for a wafer-sized high-efficiency metalens, along with a complete fabrication workflow to enable its manufacture in a cost-effective, mass-producible fashion.

In addition, metalenses further face the issue of chromatic aberration due to their reliance on the resonant transmission of light. To overcome this challenge, it is necessary to ensure that light passing through all locations of the lens arrives at the focal point simultaneously, requiring the metalens to compensate for differences in group delays (GDs) between the lens input surface and focal point.

Efforts to achieve GD compensation in metalenses have exploited the resonant dispersive phase compensation of meta-atoms combined with the geometrical phase for circularly polarized light. However, the amount of GD compensation they could provide is minimal due to the ultrathin thickness of meta-atoms. More recent attempts to improve GD compensation in metalenses through more complex meta-atom designs, such as those with ultra-high aspect ratios, multiple scattering elements, and free-form shapes have had limited success. These designs require challenging fabrication processes. Additionally, it can be difficult to find meta-atom designs that effectively balance the requirements for phase delay and GD. Ultimately, the key to improving GD compensation may lie in optimizing the entire, continuous topology of the metalens. Although this approach has the potential to improve GD compensation significantly, it is computationally challenging, limiting the size of the metalenses that can be designed, and may result in exotic nanofabrication requirements.

Therefore, multilayer structures for creating achromatic metalenses have been explored, but current multilayer designs use stacked layers of independent metalenses, where each layer is responsible for focusing at one wavelength. This limits the metalens working on only a few discrete wavelengths (usually two or three) achromatically. Moreover, the stacking method introduces loss due to the additional interfaces as well as crosstalk among the layers. They also require a one-to-one correspondence between the meta-atoms in two neighboring layers, which poses a challenge to pattern alignment during the fabrication of such metalenses.

Accordingly, there is a need for a new strategy for designing achromatic metalenses that effectively increases the GD range.

### SUMMARY OF THE INVENTION

Embodiments relate to a high-efficiency, refractive metalens capable of observing celestial bodies such as the moon. The metalens comprises a plurality of nanocylinders spatially arranged on a substrate, wherein the plurality of nanocylinders provide the metalens with an aperture having a diameter of 80 mm. The metalens is fabricated with deep-ultraviolet (DUV) projection stepper lithography, which is commonly used in the semiconductor industry.

Embodiments further relate to a multi-level-compensated metalens (MLCM) that can achieve achromatic focusing and imaging across the entire visible light spectrum (e.g., 400 nm to 700 nm). The MLCM includes nanocylinders (e.g., made of high-refractive-index silicon nitride) on top and coarse stairs (e.g., made of low-dispersion silicon nitride) at the bottom, separated by a spacer layer. The stairs provide coarse compensation for GD, while the top nanocylinders provide fine control over the GD via its resonant modes. The top nanocylinders are also responsible for imposing phase delay to transform the incident wave into a focusing wavefront. Utilizing this multi-level compensation scheme, the compound meta-atoms compensate GD profiles accurately across the entire aperture and synchronize all light at the focal point. Our method relieves the top nanocylinders from most of the GD compensation tasks, thus allowing for simpler, more fabrication-friendly nanocylinder shapes without deteriorating the performance.

In exemplary embodiment, a metalens comprises a plurality of nanocylinders spatially arranged on a substrate, wherein the plurality of nanocylinders provide the metalens with an aperture having a diameter of 80 mm.

In some embodiments, the nanocylinders have a diameter between 240 nm and 520 nm.

In some embodiments, the nanocylinders have a diameter between 240 nm and 520 nm, excluding a diameter of 400 nm.

In some embodiments, the nanocylinders comprise amorphous silicon.

In some embodiments, the substrate comprises silicon.

In some embodiments, the metalens is configured to operate in a near infrared region.

In some embodiments, the metalens has a focusing efficiency of 80.84% at 1450 nm.

In some embodiments, the metalens has a transmittance greater than 95%.

In an exemplary embodiment, a telescope comprises a metalens as described above.

In some embodiments, a method to manufacture a metalens comprises depositing a film on a substrate to provide an intermediate substrate; projecting a light pattern through a photomask and a projection lens to a first quadrant of the intermediate substrate; rotating the photomask or the intermediate substrate in 90-degree increments such that the light pattern is projected to a second quadrant of the intermediate substrate, a third quadrant of the intermediate substrate, and a fourth quadrant of the intermediate substrate; baking the intermediate substrate; and etching the film according to the light pattern to provide a plurality of nanocylinders.

In some embodiments, the film is amorphous silicon.

In some embodiments, the substrate is fused silica.

In some embodiments, the light pattern has a wavelength of 248 nm.

In some embodiments, the projection lens has a four-to-one reduction.

In some embodiments, depositing the film on the substrate to provide the intermediate substrate comprises a plasma-enhanced chemical vapor deposition.

In some embodiments, etching the film according to the light pattern to provide the plurality of nanocylinders comprises an inductively coupled plasma reactive ion etching process.

In some embodiments, the method further comprises coating the film with an anti-reflective coating after depositing the film on the substrate to provide the intermediate substrate.

In some embodiments, the method further comprises coating the film with a photoresist after depositing the film on the substrate to provide the intermediate substrate.

In an exemplary embodiment, a metalens comprises a substrate; a first film deposited on top of the substrate, wherein the first film comprises a plurality of stairs; a spacer layer coated on top of the first film layer and the substrate, wherein the spacer layer completely submerges the first film layer; and a plurality of nanocylinders spatially arranged on top of the spacer layer.

In some embodiments, the nanocylinders have a height of 600 nm.

In some embodiments, the nanocylinders comprise high refractive index silicon nitride.

In some embodiments, the plurality of stairs comprises low-dispersion silicon nitride.

In some embodiments, the substrate comprises silica.

In some embodiments, the spacer layer comprises SU-8.

In some embodiments, the metalens is configured to achieve achromatic focusing and imaging across the entire visible light spectrum.

In some embodiments, the metalens is configured to achieve an imaging performance with Strehl ratios over 90% across the entire visible spectrum.

In some embodiments, the metalens is configured to operate with a focusing efficiency of 88.12%.

In some embodiments, the spacer layer has a planar top surface.

In an exemplary embodiment, a telescope comprises a metalens as described above.

In an exemplary embodiment, a method to manufacture a metalens comprises depositing a first film on a substrate, wherein the first film comprises a plurality of stairs; coating a spacer layer on top of the first film layer and the substrate, wherein the spacer layer completely submerges the first film layer; depositing a second film on the spacer layer; and etching the second film to provide a plurality of nanocylinders.

In some embodiments, the second film comprises high refractive index silicon nitride.

In some embodiments, the first film comprises low-dispersion silicon nitride.

In some embodiments, the substrate is silica/glass.

In some embodiments, depositing the first film on the substrate comprises a plasma-enhanced chemical vapor deposition.

In some embodiments, etching the second film a to provide the plurality of nanocylinders comprises an inductively coupled plasma reactive ion etching process.

In some embodiments, the spacer layer is etched to form a planar/flat top surface after the spacer layer is coated on top of the first film layer and the substrate.

### BRIEF DESCRIPTION OF THE DRAWINGS

The above and other objects, aspects, features, advantages and possible applications of the present innovation will be more apparent from the following more particular description thereof, presented in conjunction with the following drawings. Like reference numbers used in the drawings may identify like components.

FIG. 1 shows an exemplary single layer metalens.

FIG. 2 shows an exemplary method of manufacturing a single layer metalens.

FIG. 3 shows an exemplary method of manufacturing a single layer metalens.

FIG. 4 shows an exemplary multi-level-compensated metalens.

FIG. 5 shows exemplary stairs of an exemplary multi-level compensated metalens.

FIG. 6 is a schematic representation of the combination of SiN stairs and top nanocylinders, providing both coarse and fine group delay compensation (the lines illustrate the group delay distributions).

FIG. 7 is an illustration of broadband white light being focused by an exemplary MLCM.

FIG. 8 shows simulated phase and transmittance response of amorphous silicon nanocylinders with different diameters ranging from 200 nm to 800 nm.

FIG. 9 shows meta-atom designs for metalens with phase and transmittance responses.

FIG. 10 shows a layout pattern of a small metalens with a 40 μm aperture as numerical validation.

FIG. 11 shows a light intensity distribution on the xOz cross-session after the metalens simulated by a full-wave finite-difference time-domain solver.

FIG. 12 shows a light intensity distribution at the metalens' focal plane at z=100 μm.

FIG. 13 shows fabrication test result for the relationship between the measured diameter of the fabricated nanocylinders and the designed diameters in the input layout.

FIG. 14 shows a schematic illustration of the exposure process of DUV lithography for large-scale metalenses fabrication.

FIG. 15 shows a photograph of the four reticles used in the DUV lithography process.

FIG. 16 shows the rotating method used during DUV exposure.

FIG. 17 shows a schematic of the fabrication process flow.

FIG. 18 shows a photograph of an 80-mm-aperture metalens.

FIG. 19 shows a tilted-beam scanning electron micrograph (SEM) of a metalens that reveals nanocylinders of different sizes and vertical sidewalls.

FIG. 20 shows an SEM image of meta-atoms (scale bar=600 nm).

FIG. 21 shows a schematic of the experimental setup for characterizing the focusing performance of the metalens.

FIG. 22 shows intensity profiles of the focused beam after the metalens along both xOy and yOz cross-sections with the wavelength ranging from 1200 nm to 1600 nm.

FIG. 23 shows measured focal lengths of the fabricated metalens with the wavelength ranging from 1200 nm to 1600 nm.

FIG. 24 shows measured focal spot FWHM of the fabricated metalens with the wavelength ranging from 1200 nm to 1600 nm.

FIG. 25 shows measured total focusing efficiency of the fabricated metalens with the wavelength ranging from 1200 nm to 1600 nm.

FIG. 26 shows captured images of the USAF 1951 resolution chart formed by the 4-inch-aperture metalens.

FIG. 27 shows an IR image of the moon formed by the metalens.

FIG. 28 shows a photograph of the metalens telescope which was being used to capture the moon's image.

FIG. 29 shows an SEM image of the central part of large-scale metalens (scale bar=200 μm).

FIG. 30 shows a tilt view of the edge area of the large-scale metalens, which includes the smallest and largest nanocylinders (scale bar=2 μm).

FIG. 31 shows a close-up view of stitching area written by different reticles (scale bar=2 μm).

FIG. 32 shows an optical image near the edge of the metalens.

FIG. 33 shows the experiment setup for the metalens efficiency measurement. The photodetector of the power meter was placed at three positions labeled (i), (ii), and (iii) for light intensity measurement.

FIG. 34 shows an exemplary fitting the measured intensity values to a Gaussian function to determine the intensity distribution and total incident/transmitted power in front of/behind the metalens.

FIG. 35 shows Strehl ratio measurement and simulation results.

FIG. 36 shows a phase-GD diagram with extended achievable group delay range by the meta-atoms with six variations of bottom SiN stair thicknesses.

FIG. 37 shows phase and group delay provided by the nanoantennae alone (with a fixed bottom SiN stair thickness).

FIG. 38 shows material index (left) and loss coefficients (right) of the silicon nitride films deposited under various conditions and with different compositions (gas ratio SiH₄:NH₃=a).

FIG. 39 shows the dispersion of the refractive indices of the high-index SiN (nanoantennas), SU8, and low-dispersion SiN (stairs).

FIG. 40 shows the surface formed by the required phase and local average group delay (LAGD) at different frequencies of the achromatic MLCM to be designed, along with the meta-atom phase-LAGD point clusters at various frequencies.

FIG. 41 shows the effect of the two-step optimization process used to simplify the height profile of the stairs. The left portion indicates regions with fast oscillating stair heights, while the right portion show the simplified stair height profiles in these regions with smooth transition after the two-step process.

FIG. 42 shows a comparison between the theoretical phase profile (lines) and the realized phase profile (dots) of the designed achromatic MLCM across the seven equally spaced wavelengths.

FIG. 43 shows a tilted-beam scanning electron micrograph (SEM) of SiN stairs (scale bar=30 μm) (inset shows microscope image of the SiN stairs; scale bar=50 μm).

FIG. 44 shows a top-view SEM image of the achromatic metalens (scale bar=800 nm) (inset shows a tilted-beam SEM of the nanoantennas, revealing highly vertical sidewalls; scale bar=600 nm).

FIG. 45 shows an exemplary optical setup for the characterizations.

FIG. 46 shows transverse (bottom panels) and longitudinal (top panels) cross-sections of the light intensity distribution in the proximity of the focus at seven equally spaced wavelengths from 400 nm to 700 nm. The dashed line indicates the designed focus position.

FIG. 47 shows measured focal length versus wavelength change.

FIG. 48 shows measures full-width-at-half-maximum of the focal spot versus wavelengths, in comparison with the theoretically calculated diffraction-limited value.

FIG. 49 shows measured Strehl ratio of the focus spots versus wavelengths. A reference value of 0.8 (considered diffraction-limited) is shown by the dashed line.

FIG. 50 shows an imaging test of the achromatic MLCM.

FIG. 51 shows an experiment setup for metalens imaging characterization.

FIG. 52 shows a T-matrix calculation of meta-atom phase and transmission spectrum.

FIG. 53 shows a detailed fabrication process of bottom stair layers, SU8 spacer, and SiN meta-atoms.

FIG. 54 shows an exemplary method of manufacturing a single layer metalens.

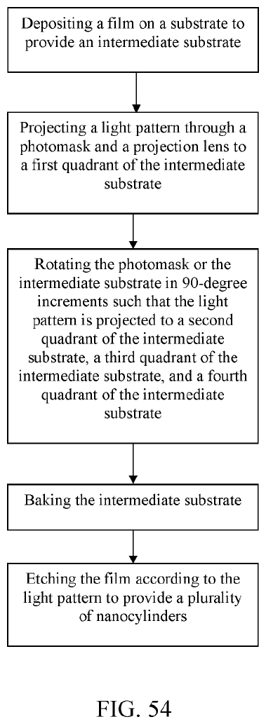

FIG. 55 shows an exemplary method of manufacturing a multi-level-compensated metalens.

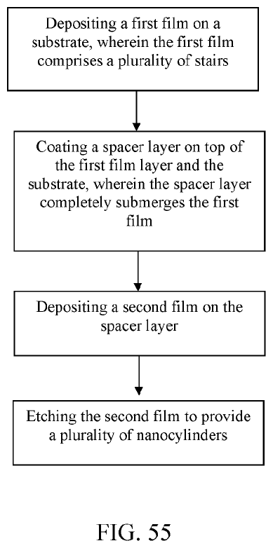

### DETAILED DESCRIPTION OF THE INVENTION

The following description is of exemplary embodiments and methods of use that are presently contemplated for carrying out the present invention. This description is not to be taken in a limiting sense, but is made merely for the purpose of describing the general principles and features of various aspects of the present invention. The scope of the present invention is not limited by this description.

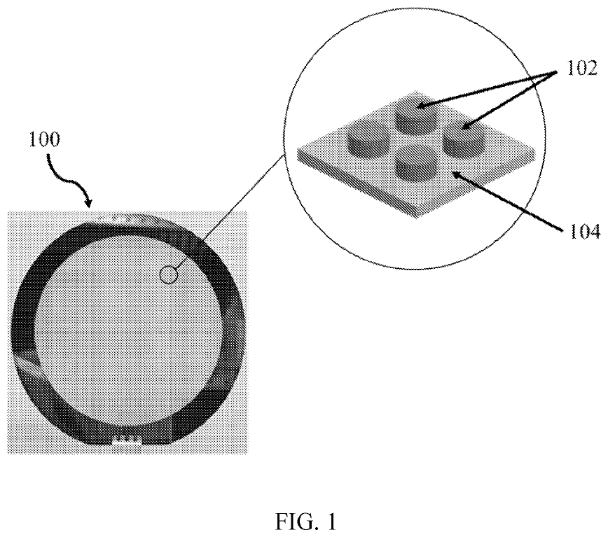

As seen in FIG. 1, a first embodiment relates to a metalens 100 (or metasurface lens)—an artificial interface that molds light with spatially varying subwavelength nanocylinders 102 (or meta-atoms), and particularly to a single-layer metalens 100. The metalens 100 is generally ultrathin and lightweight. The thickness of the metalens 100 can range from a few hundred nanometers to a few microns, depending on the design. The weight of the metalens 100 is dependent on its size, but is contemplated to be negligible (e.g., less than 0.5 grams).

In exemplary embodiments, the nanocylinders 102 may be formed on a surface of a substrate 104. The surface of the substrate 104 may be patterned with an array of nanocylinders 102. According to various embodiments, the array of nanocylinders 102 may be uniformly spaced, periodically spaced, aperiodically spaced, and/or arranged in repeating patterns of the same.

Each nanocylinder 102 in the array of nanocylinders 102 may have subwavelength dimensions. In some embodiments, the nanocylinders 102 may extend substantially orthogonal to the planar surface of the substrate 104, such that the nanocylinders 102 have vertical or near vertical side walls.

In various embodiments, the cross-section of a nanocylinder 102 contacting the substrate 104 may be any shape. In a preferred embodiment, the cross-section of a nanocylinder 102 is circular or substantially circular. The cross-section of a nanocylinder 102 have diameters ranging from 200 nm to 800 nm, preferably from 240 nm to 520 nm, as such range covers a complete 2π phase range (excluding 400 nm diameter due to low transmittance and rapid phase changes). The nanocylinders 102 may extend from the substrate 104 to a height ranging from a few hundred nanometers to a few microns (e.g., 200 nm to 2000 nm).

In some embodiments, each nanocylinder 102 may be formed from high-index materials fused on the substrate 104. The high-index materials may be silicon (e.g., amorphous silicon), titanium dioxide, silicon nitride, gallium nitride, and other like high-index materials.

In some embodiments, the substrate 104 may be materials that are transparent in the wavelength ranges of interest, such as glass (e.g., silica), sapphire, zinc selenide, and other like materials. In particular, the substrate 104 may be a glass wafer. The substrate 104 may have a diameter (or width) ranging from a few microns to a few inches, depending on a particular application. It is contemplated that a role of the substrate 104 is to provide mechanical support to the metalens 100. The substrate 104 may have a thickness ranging from a few microns to a few millimeters.

The pattern of an array nanocylinders 102 may be repeated multiple times to provide a metalens 100 with an aperture having a diameter (or width) of, e.g., 80 mm, or 80 mm or less. The aperture of the metalens 100 may be defined as the target surface area configured to collect and focus light. The aperture may be any shape. In a preferred embodiment, the aperture is circular or substantially circular.

The metalens 100 is configured to operate in the near-infrared region with nearly diffraction-limited focal spot sizes. The metalens 100 is further configured to operate with a focusing efficiency of 80.84% at 1450 nm.

The metalens 100 is configured such that only nanocylinders 102 with greater than 95% transmittance were chosen to ensure the high efficiency of the resulting metalens 100.

Accordingly, the transmittance of the metalens 100 is over ˜95%.

The metalens 100 may be fabricated using a deep-ultraviolet (DUV) photolithography technique. The DUV photolithography technique is advantageous, as it allows costly, time-consuming scanning-based processes for large-area densely packed nanocylinders to be avoided.

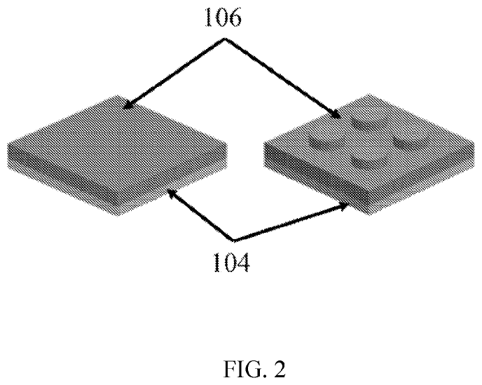

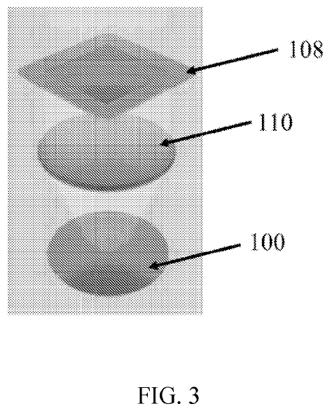

As seen in FIGS. 2 and 3, in accordance with the DUV workflow, a film 106 may be deposited on the substrate 104. It is contemplated that the film 106 may be deposited on the substrate 104 using any suitable technique, including plasma-enhanced chemical vapor deposition (PECVD). It is understood that the film 106 ultimately results in nanocylinders 102. It is contemplated that the film 106 may be amorphous silicon or other like high-index materials. It is further contemplated that the film 106 may have a thickness of 1 μm.

In some embodiments, a light source with a 248 nm wavelength and a photomask 108 may be used for the DUV system. Other light sources (e.g., 193 nm, 97 nm DUV sources) may alternatively be used to perform photolithography. It is understood that the smaller the light source wavelength, the finer the fabricated structures may be. The photomask 108 is used to project light patterns to the substrate 104 through a projection lens 110 with 4 to 1 reduction ratio. The substrate 104 (or photomask 108) may be rotated 90 degrees (either clockwise or counterclockwise) to allow the substrate 104 to be exposed to light at all quadrants of the substrate 104. After exposure, the metalens 100 is then baked. After baking, a dry etching process, such as an inductively coupled plasma reactive ion etching process, may be used to transfer the exposed pattern to the film 106 layer below, thus providing the resulting nanocylinders 102.

In some embodiments, the film 106 may be coated with an anti-reflective coating after it is deposited on the substrate 104. In some embodiments, the film 106 may be coated with a photoresist after it is deposited on the substrate 104.

It is contemplated that the above-described method of manufacturing a metalens 100 may be specific to a single layer metalens.

The above-described metalens 100 may be utilized in a telescope. It is contemplated that such telescope would be a compact, versatile, and energy efficient system for remote sensing and imaging. Accordingly, it is contemplated that such telescope and/or metalens 100 could be used in a number of different fields, including but not limited to, aircraft, unmanned vehicles, drones, and satellites, as well as in consumer products such as virtual reality (VR), augmented reality (AR), and mixed reality (MR) devices.

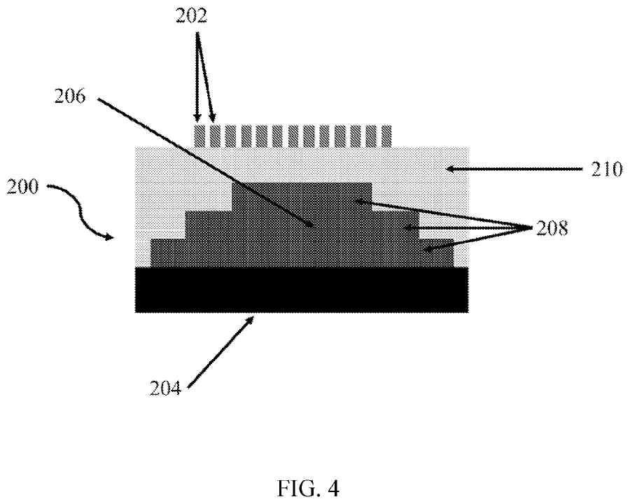

As seen in FIG. 4, a second embodiment relates to a multi-level-compensated metalens 200 (MLCM) with spatially varying subwavelength nanocylinders 202 (or meta-atoms).

In exemplary embodiments, the metalens comprises a substrate 204. The substrate 204 may be a material that is transparent in the wavelength ranges of interest, such as glass (e.g., silica), sapphire, zinc selenide, and other like materials. It is contemplated that a role of the substrate 204 is to provide mechanical support to the metalens 200. The substrate 204 may have a thickness ranging from a few microns to a few millimeters.

In exemplary embodiments, a first film 206 is deposited on the substrate 204. It is contemplated that the first film may comprise low-dispersion silicon nitride (SiN). It is contemplated that the first film 206 may be etched to form a plurality of stepped layers/stairs 208. As used herein, stairs 208 generally describes 208′, 208″, and/or 208′″. It is contemplated that any number of stairs 208 may be used in the metalens 200.

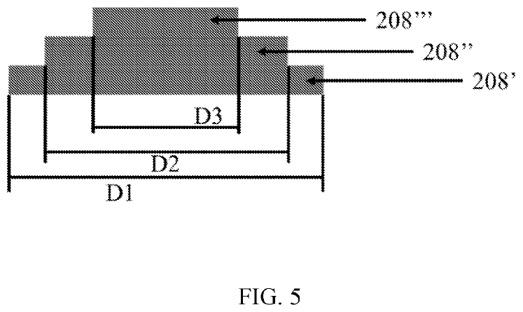

For example, as seen in FIG. 5, stair 208′ may form a base/bottom layer with a first diameter D1, stair 208″ may form an intermediate later with a second diameter D2, and stair 208′″ may form a top layer with a third diameter D3, such that D1>D2>D3, thus giving the first film 206 its stair-like structure. It is contemplated that the thicknesses (defined as the distance the top of a stair to the bottom of a stair) of the stairs 208 may be the same or different as one another.

The metalens further comprises a spacer layer 210 positioned on top of the first film and/or substrate 204. The spacer layer 210 may be any suitable material. In a preferred embodiment, the spacer layer 210 comprises SU-8 material. It is contemplated that the spacer layer 210 completely submerges the stairs 208. It is contemplated that the spacer layer 210 forms a planar/flat top surface.

In exemplary embodiments, the nanocylinders 202 may be fused on the top planar surface of the spacer layer 210. The top planar surface of the spacer layer 210 may be patterned with an array of nanocylinders 202. According to various embodiments, the array of nanocylinders 202 may be uniformly spaced, periodically spaced, aperiodically spaced, and/or arranged in repeating patterns of the same.

Each nanocylinder 202 in the array of nanocylinders 202 may have subwavelength dimensions. In some embodiments, the nanocylinders 202 may extend substantially orthogonal to the planar surface of the substrate, such that the nanocylinders have vertical or near vertical side walls.

In various embodiments, the cross-section of a nanocylinder 202 may be any shape. In a preferred embodiment, the cross-section of a nanocylinder 202 is a shape that possesses C⁴ symmetry, such as a circular shape, a square shape, or substantially circular shape.

Each nanocylinder 202 may extend from the substrate 204 to a height ranging from a few hundred nanometers to a few microns (e.g., 200 nm to 2000 nm), and particularly to a height of 600 nm.

The pattern of an array nanocylinders 202 may provide the MLCM 200 with an aperture having a diameter (or width) of, e.g., 0.4 mm, or 0.4 mm or less. The aperture of the MLCM 200 may be defined as the target surface area configured to collect and focus light. The aperture may be any shape. In a preferred embodiment, the aperture is circular or substantially circular.

In some embodiments, the nanocylinders 202 comprise high-refractive index SiN.

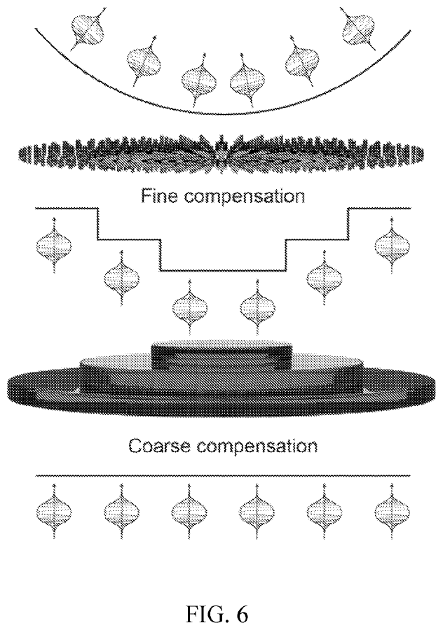

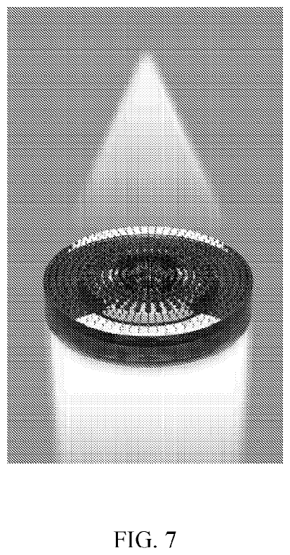

As seen in FIGS. 6 and 7, stairs 208 provide coarse compensation for group delay (GD), while the nanocylinders 202 provide fine control over the GD via its resonant modes. The nanocylinders 202 are also responsible for imposing phase delay to transform the incident wave into a focusing wavefront. This may be considered a multi-level compensation scheme. Specifically, this configuration relieves the nanocylinders 202 from most of the GD compensation tasks, thus allowing for simpler, more fabrication-friendly nanocylinder shapes without deteriorating the performance.

The MLCM 200 is configured to achieve achromatic focusing and imaging across the entire visible light spectrum (e.g., 400 nm to 700 nm).

The MLCM 200 is further configured to produce diffraction-limited focusing and imaging performance with Strehl ratios over 90% across the entire visible spectrum. The MLCM provides a focal length deviation across the visible band as small as 1.61% of the designed focal length. The MLCM 200 is further configured to operate with a focusing efficiency of 88.12%.

The MLCM 200 may be fabricated by depositing the first film 206 on the substrate 204. The first film 206 may be deposited using PECVD (e.g., with the gas ratio NH₃:SiH₄=140:35). Alignment of the stairs 208 may be marked with gold markers and defined using E-beam lithography (e.g., using EBPG Vistec 5200). The stairs 208 may be formed by dry etching (e.g., using ICP-RIE).

In some embodiments, the spacer layer 210 may be spin coated on the stairs 208/substrate 204 such that the spacer layer 210 completely submerges the stairs 208. The spacer layer 210 may further be back etched to decrease its thickness and/or to form a planar/flat top surface.

In some embodiments, a second film may be deposited on the spacer layer 210. It is contemplated that the second film may be deposited on the spacer layer 210 using any suitable technique, including PECVD. It is understood that the second film ultimately results in nanocylinders 202. It is contemplated that the second film may be high-index SiN. A dry etching process, such as an inductively coupled plasma reactive ion etching process, may be used to provide the resulting nanocylinders 202.

It is contemplated that the above-described method of manufacturing a metalens 200 may be specific to a MLCM.

The above-described metalens 200 may be utilized in a telescope.

### Examples

### Single Layer Metalens

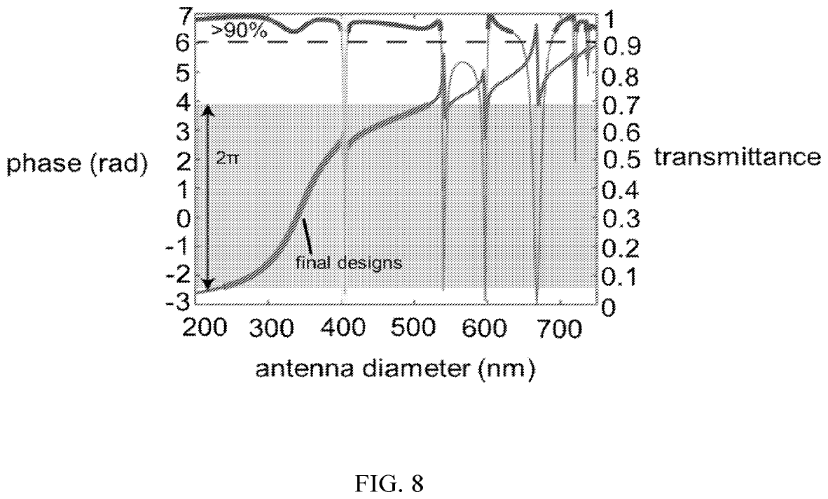

The large-aperture metalens, the core of the metalens telescope, was designed by calculating the required phase profile

$$φ ( r ) = - \frac{2 π}{λ} [ \sqrt{( {r}^{2} + {f}^{2} )} - f ] ,$$

where f is the focal length of the metalens, λ is the wavelength of the incident light, and r is the radial position on the lens. The nanocylinders (e.g., nanoantennas), which are the meta-atoms of the metalenses, were made of amorphous silicon on a fused silica substrate. Simulating the nanocylinders using a full-wave solver, it was found that a complete 2π phase coverage can be achieved with nanocylinders' diameters ranging from 240 to 520 nm (FIG. 8). A resonance near 400 nm is excluded to ensure a smooth change of phase. In addition, only antennas with greater than 95% transmittance were chosen to ensure the high efficiency of the resulting metalenses.

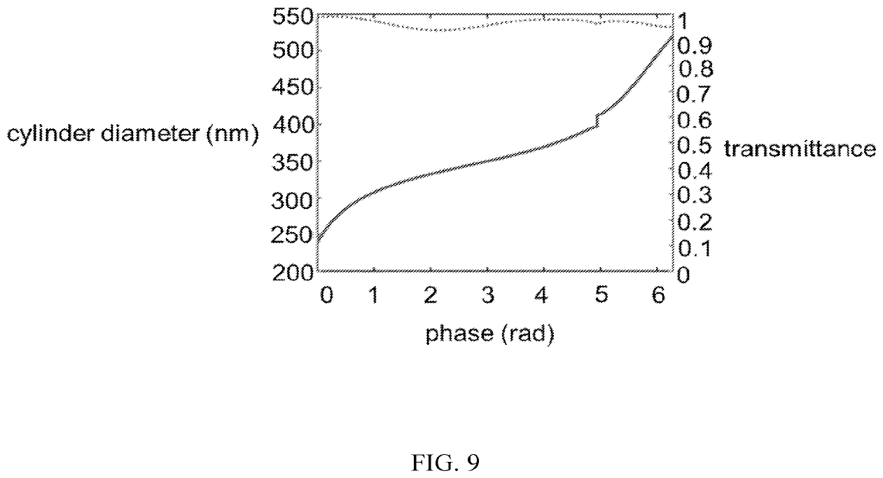

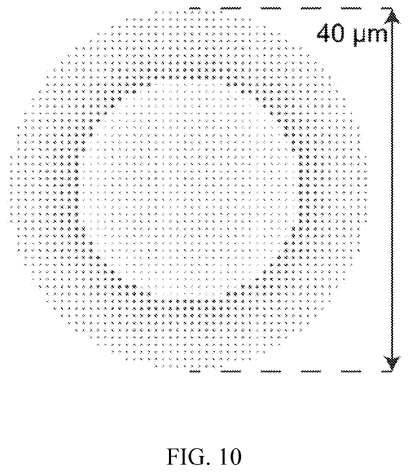

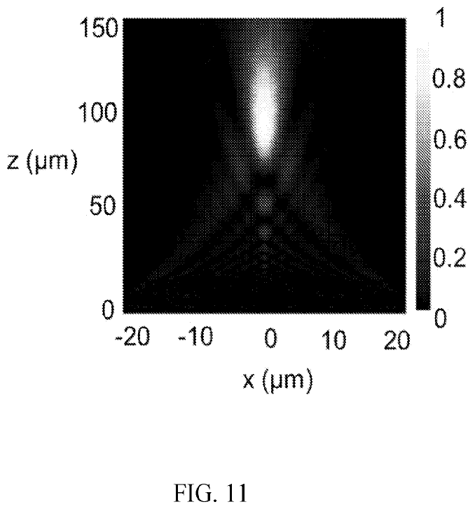

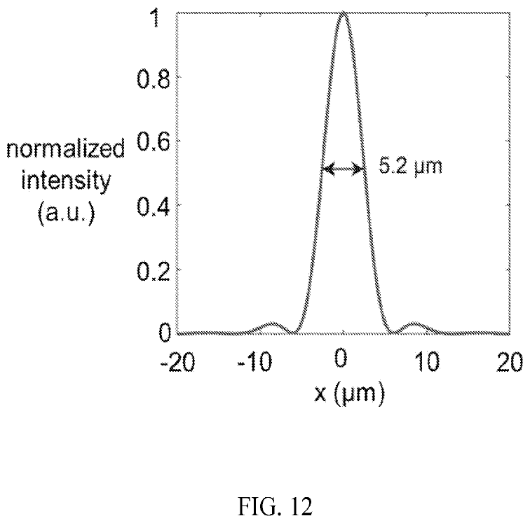

Before simulating and designing the wafer-scale metalens, the resolution test for the DUV stepper and DWL2000 laser writer was needed to determine the minimum resolvable feature size and the relationship between pattern size in CAD files and fabricated samples. In the resolution test, square and circular patterns were designed, and it was found that circles with small feature sizes can survive while squares with small feature sizes were blurred to circles. The smallest feature size for circles is less than 200 nm after the whole fabrication process, but the size relationship for the antennas below 200 nm diameter was not stable. The phase and transmission responses of amorphous Si nanocylinders with diameters ranging from 200 nm to 800 nm were scanned). According to the design, it was found that a 2π phase range can be achieved from 240 nm to 520 nm. The resonance part was removed near 400 nm and the phase-diameter relationship with all the transmission larger than ˜95% was observed (FIG. 9). A 40 μm-diameter metalens was designed for validating the design numerically (FIG. 10). The light intensity distributions after small-size metalens from the full-wave simulation indicate the diffraction-limited focusing performance of the metalens (FIGS. 11-12).

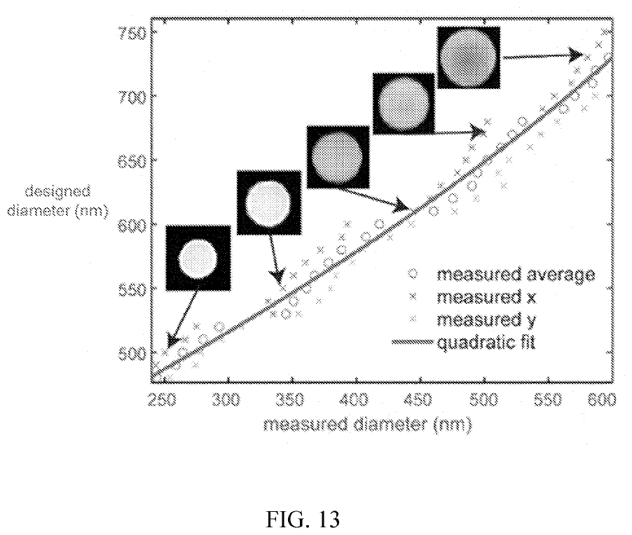

In order to achieve accurate sizes for the patterns, the relationship between the input meta-atom dimensions and the fabricated meta-atom dimensions measured in scanning electron micrographs (SEMs) was first established by multiple dose- and etching-tests (FIG. 13). A quadratic fitting was then used to relate the meta-atom dimensions in the layout and the fabricated patterns, which guarantees that the fabricated antennas' dimensions match the required ones. The radial symmetry of the metalens phase profile allowed the layout file size to be reduced to a reasonable level. Only a lookup table (LUT) and the meta-atom positions were stored. The circular cross-sections of the corresponding meta-atoms were approximated with polygons. The designs of the meta-atoms were determined based on their positions via the LUT. For the 80-mm metalens, the layout file was about 240 GB with a 5-nm increment in meta-atom diameters. The pattern layout files were generated corresponding to the required phase profile with both correction and compression.

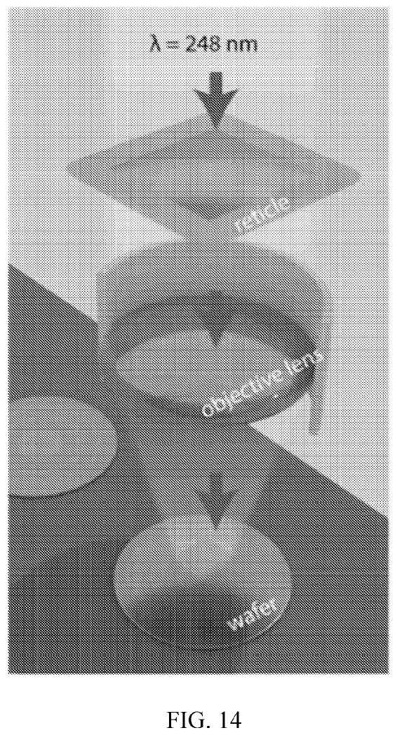

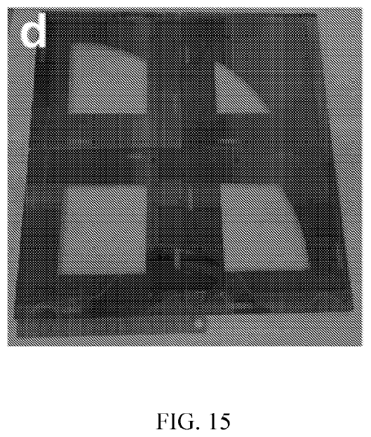

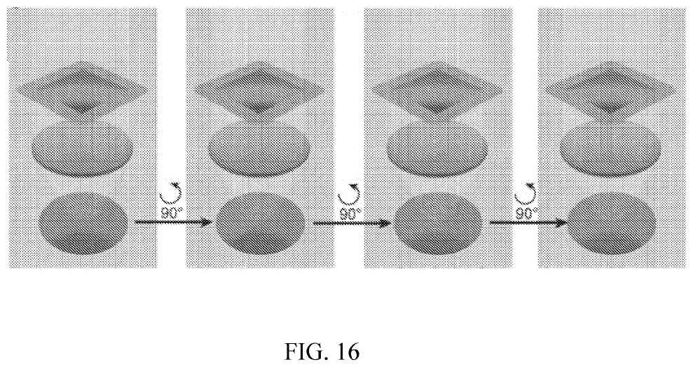

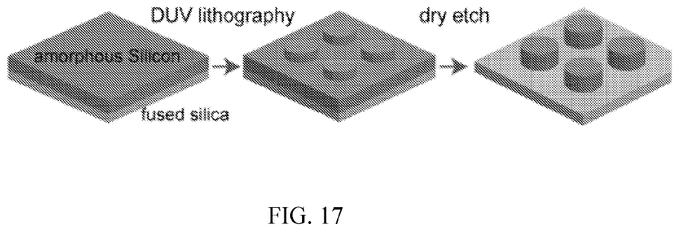

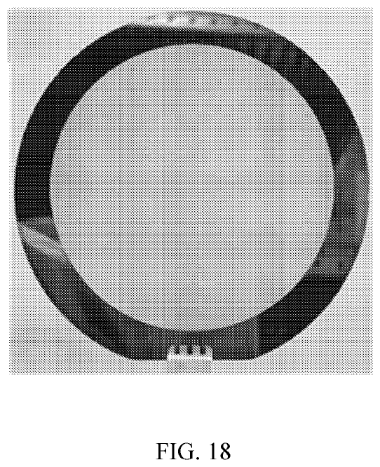

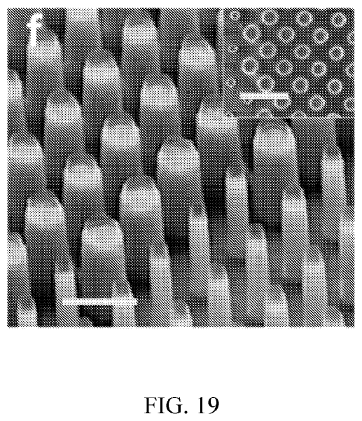

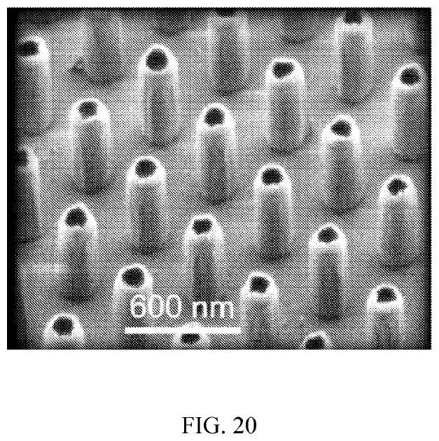

The metalens was fabricated with a customized DUV lithography workflow. Considering the maximum area for a single exposure of the DUV tool is a 22-mm-by-22-mm field, patterns were divided into 16 pieces, with each piece a 20 mm×20 mm square for exposure. Exploiting the C⁴ rotational symmetry of the metalens, only four reticles were needed to cover a quarter of the metalens, simplifying the lithography process. The four reticles were made with the pattern size magnified four times for the projection lithography (FIGS. 14-15). The metalens pattern was transferred onto a four-inch fused silica wafer by a DUV stepper with four reticles at a 4:1 reduction ratio (FIG. 14). The exposure process for 16 fields can be done either by reticle rotation (rotation markers needed on the reticles) or wafer rotation (rotation markers needed on wafers) with appropriate stitching for different fields. In the exposure process, four reticles were loaded into the Stepper. A quarter of the metalens pattern, consisting of four 20 mm×20 mm fields, was exposed through four different reticles. The other three quarters were exposed by rotating the relative position of reticles and wafers by 90°, 180°, and 2700 (FIG. 16). The exposed pattern was followed by post-exposure bake and development and then transferred to the amorphous silicon layer below through the inductively coupled plasma reactive ion etching process. The entire process flow is shown in FIG. 17, and the fabricated metalens is shown in FIG. 18. It was observed that the stitching error among different fields was less than 1 μm, which has negligible influence on the performance of the metalens. Characterization of the fabricated metalens by SEM shows that the constituent nanocylinder antennas match well with the design (FIGS. 19-20). In summary, the DUV photolithography-based fabrication method embraces both precision and simplicity while eliminating the need for scanning-based pattern writing, thus significantly reducing cost and time and being suitable for the mass production of commercial telescopes.

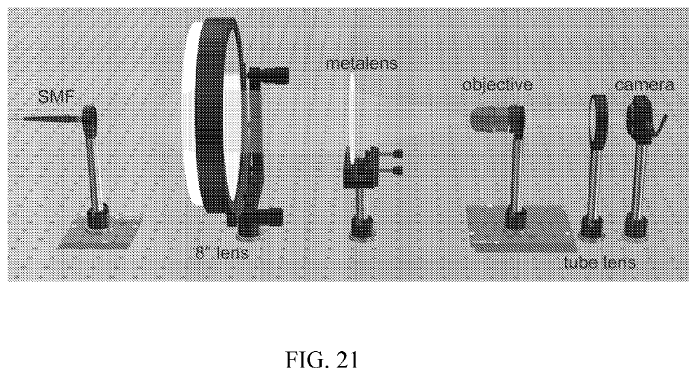

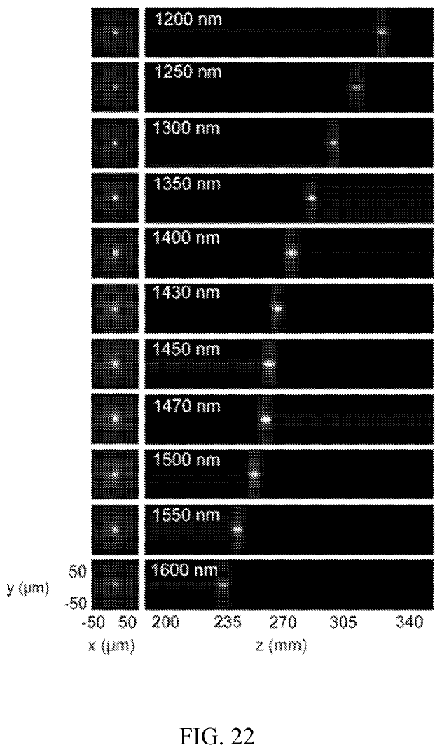

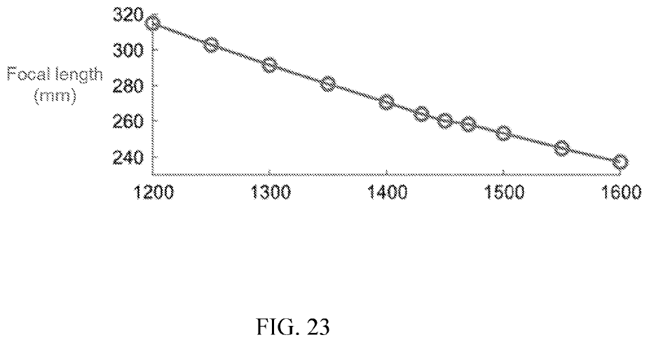

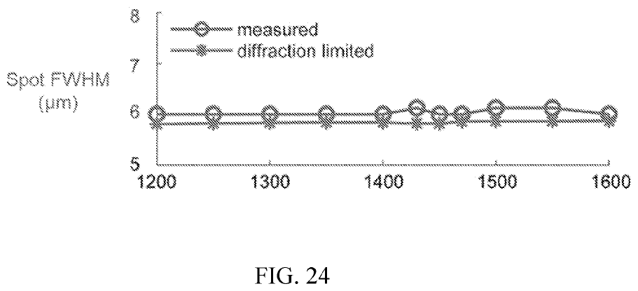

With the metalens fabricated, the optical performance specifications of the fabricated metalens were characterized with a homemade optical platform. For focusing measurements, the point spread function (PSF) was captured using an imaging system, as shown in FIG. 21. By tuning the output wavelength of the incident light and translating the objective lens along the optical axis, the intensity profile of the focused beams along both yOz and xOy cross-sections was characterized over a broad wavelength range, from 1200 nm to 1600 nm (FIG. 22). The measurement shows that, although the metalens was designed to operate at the 1450 nm wavelength, it could still focus light tightly across the tested wavelength range, with varying focal lengths due to diffractive dispersion. The measured focal lengths show a roughly linear dependence with the incident wavelength (FIG. 23). Further, the quality of each focal spot was evaluated by extracting its full width at half maximum (FWHM) and comparing it to that of a diffraction-limited system with the same numerical aperture (NA). The results show that the measured FWHMs were close to diffraction-limited values across all wavelengths (FIG. 24). Note that the NAs used for determining the diffraction-limited spot sizes were calculated based on the metalens aperture size and the measured focal lengths at each wavelength.

The Strehl ratio (SR) is a criterion commonly used in optical industries to characterize the aberrations of the optical system. The Strehl ratio of the metalens imaging system was calculated through the measured PSF in the following way. First, the ideal PSF was calculated based on the diffraction-limited FWHM value (FWHM=0.514λ/NA) and normalized the ideal PSF so that its value at the center equals unity. Second, the measured PSF was normalized to have the same integral as the ideal PSF across the cross-section. Finally, the ratio of the measured and ideal integral values is the SR. The calculated SR of the metalens system is around 0.5 for all the wavelengths. However, it should be noted that this SR indicates the focusing performance of the entire measurement system rather than the metalens alone. It was significantly affected by the measurement instruments, for instance, the imperfection of the input wavefront caused by the 8-inch plano-convex collimation lens which has a large spherical aberration. This SR value does not directly represent the actual performance of the metalens. However, after further analysis, the SR of the system was found to be around 0.7 even if the metalens was replaced with a perfect lens in the measurement system. This indicates that the metalens did perform well, which is not much worse than an ideal lens. The discrepancy mainly originated from other limiting factors such as substrate thickness non-uniformity, fabrication imperfections, etc.

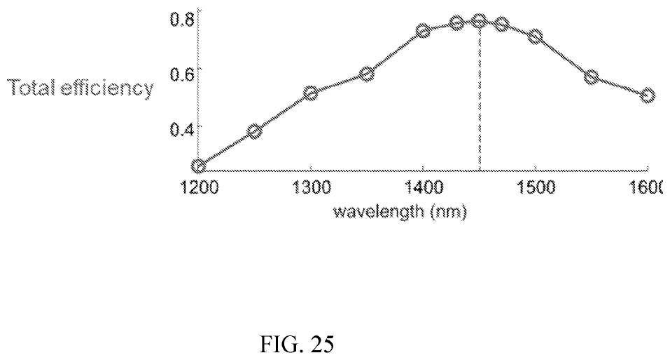

Finally, the focusing efficiencies of the metalenses were measured using an optical power meter. In order to accurately measure the input intensity distribution before the metalens and the focused power, a pinhole was mounted in front of the photodetector. The purpose of the pinhole is twofold: (1) to sample the intensity distribution in front of the metalens and fit with a two-dimensional Gaussian profile to determine the incident light power; (2) to limit the detector aperture to only capture light within an area across about three times of the FWHM of the focal spot size at the metalens focal plane. The measured focusing efficiency reaches its maximum at 1450 nm, with a value of 80.84% (FIG. 25). These results suggest that, with a tight focus as well as excellent efficiency, the metalens can serve as a telescope objective.

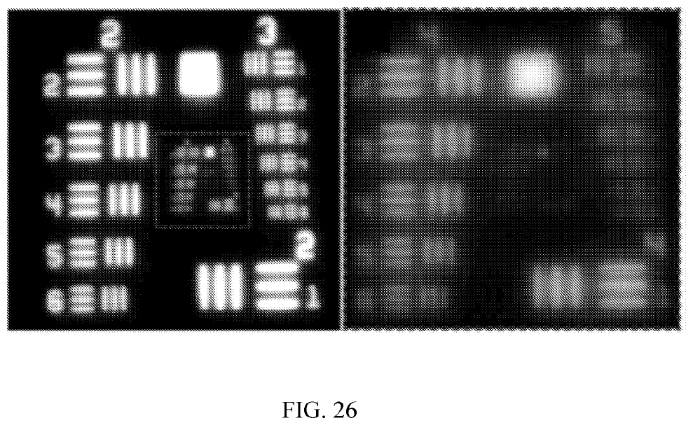

Next, the imaging performance of the metalens was tested in both laboratory and outdoor environments to determine its resolving power. The USAF 1951 resolution test chart was imaged with the single-lens imaging configuration and the as-captured grayscale image (FIG. 26). A beam expander and bandpass filter were used to ensure uniform monochromatic illumination. The smallest feature that could be resolved was Group 5, Element 6 in the resolution test chart, with a line width of 8.77 μm (57 line pairs/mm). This value is close to the focal spot FWHM measured earlier, which means that the limit of the resolving power of the metalens was reached.

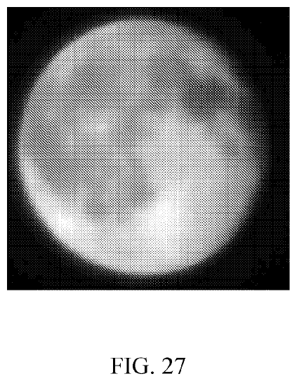

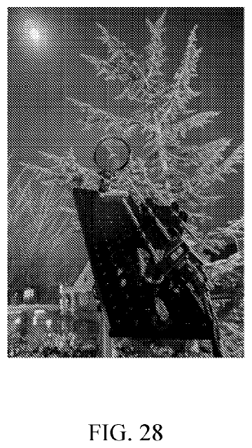

Finally, the metalens telescope was built with the fabricated metalens. The image was magnified 2× by an image relay system before being captured by the camera to fully utilize its pixels. The system was assembled on an optical breadboard mounted on a commercial camera tripod. Through this metalens telescope, the lunar surface was imaged in an outdoor environment (FIGS. 27-28). Some features of the lunar surface were identified, such as the Sea of Rains, the Sea of Serenity, the Sea of Tranquility, the Ocean of Storms, the Sea of Tranquility, and the Copernicus crater, from the obtained image.

### Materials and Methods

### Metalens Fabrication

The metalens was fabricated on a 4-inch fused silica substrate. First, 1 μm of amorphous silicon was grown on top of the substrate by plasma-enhanced chemical vapor deposition (PECVD). Then the anti-reflective coating and photoresist were spin-coated on top of amorphous silicon, followed by pre-baking. Next, the wafer was exposed using a KrF excimer laser of an ASML DUV stepper with four reticles through the rotation and stitching process. Heidelberg MaskWriter DWL2000 was used to write the reticles, and the size is magnified patterns of the layout by four times for ASML stepper usage.

### Reticle Fabrication

A 6″×6″×0.250″ photomask blank (Telic company) with a low reflective chrome layer (8% reflective @450 nm) and 530-nm AZ 1500 photoresists was used for the fabrication of reticles. After writing the metalens patterns (magnified by 4×) and the alignment markers for rotation on photomasks with a DWL2000 laser writer, AZ 300 MIF developer was used to develop the photoresist layer. The final Cr patterns were wet etched with the resist masks, and the reticles were made after removing the remaining resist in a solvent.

### Error Analysis

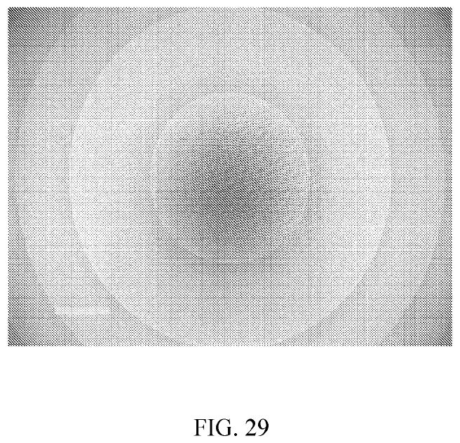

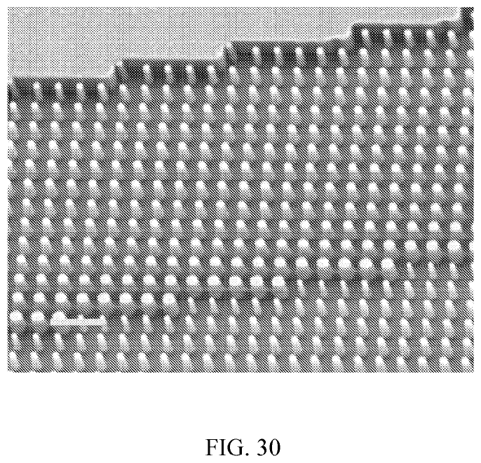

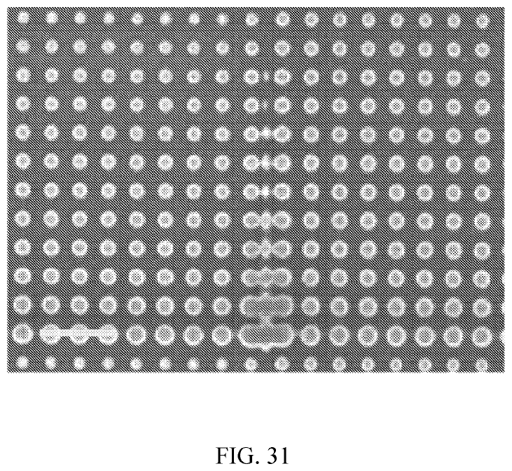

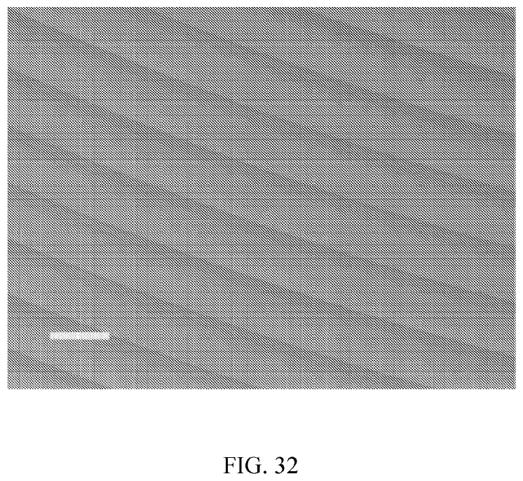

FIG. 29 shows the SEM images near the center, and FIG. 30 shows the tilt view of antennas near the corner. Some merged patterns can be found in the stitching area of the patterns exposed by two reticles (FIG. 31). We found the stitching error is less than 1 μm. The faintly visible vertical lines with a period of 40 μm shown in FIG. 32 originated from the stitching error of the DWL2000 laser writer, which writes line by line with a period of 160 μm. The period becomes 40 μm after 4:1 reduction in the exposure process.

### Optical Characterization

For focusing capability measurements, laser output from a single-mode fiber end was collimated by an 8-inch-aperture plano-convex lens (effective focal length: 400 mm), which expanded the beam diameter to ˜100 mm. The focal spot behind the metalens was imaged by an infinity-corrected imaging system. The imaging system has a magnification of 50×. For imaging capability measurements, the USAF resolution test chart was illuminated by a halogen lamp. The light from the lamp was expanded using a 2F-2F relay system with 2× magnification to get a more uniform illumination. A bandpass filter (Thorlabs FB1450-12), with a 1450 nm central wavelength and a 12 nm bandwidth, was mounted on the camera to reduce the background noise.

For focusing capability measurements, laser output from an optical parametric oscillator (OPO with FWHW around 20 nm at 1450 nm) pumped by a Ti:Sapphire fs-pulse laser system was coupled into a single-mode fiber (Thorlabs P1-SMF28E-FC-10). At the other end of the fiber, an 8-inch-aperture plano-convex lens (effective focal length: 400 mm) was used as a beam expander and collimator. The expanded incident beam was larger than the metalens, which ensures that the entire metalens aperture is illuminated by a plane-wave-like incidence. After the beam passed through the metalens, the focal spot was imaged by a long-working-distance NIR objective lens mounted on a motorized linear translation stage (Newport ILS50CC with ESP 300 controller). Finally, the focal spot images were captured by an InGaAs infrared camera (Sensors Unlimited, GA640CB) placed at the back focal plane of a 2-inch wide-angle tube lens with a 200 mm focal length. The imaging system has a magnification of 50×.

For imaging capability measurements, the USAF resolution test chart was illuminated by a halogen lamp with 2× magnification. The test chart and the IR camera were placed ˜2 focal lengths away, in front of and behind the metalens, respectively. A bandpass filter (Thorlabs FB1450-12), with a 1450 nm central wavelength and a 12 nm bandwidth, was mounted on the camera to reduce the background noise. The camera's position was fine-tuned by a motorized translation stage (Newport UTS150CC with ESP 300 controller) to ensure the best image quality.

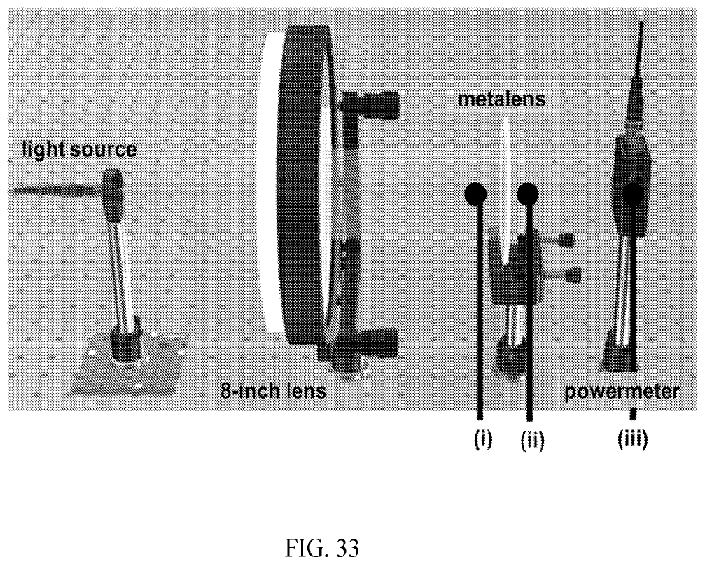

A power meter and the corresponding photodetector with a mounted pinhole was used for the metalens efficiency measurement. The experiment setup is shown in FIG. 33, where the photodetector was placed in the following positions for the measurement:
(i) Right before the metalens
(ii) Right after the metalens
(iii) Right at the focal spot of the metalens

To determine the total focusing efficiency of the metalens, only results from (i) and (iii) are needed. However, at the peak efficiency wavelength (1450 nm), results at position (ii) were also measured to determine the transmission efficiency of the metalens.

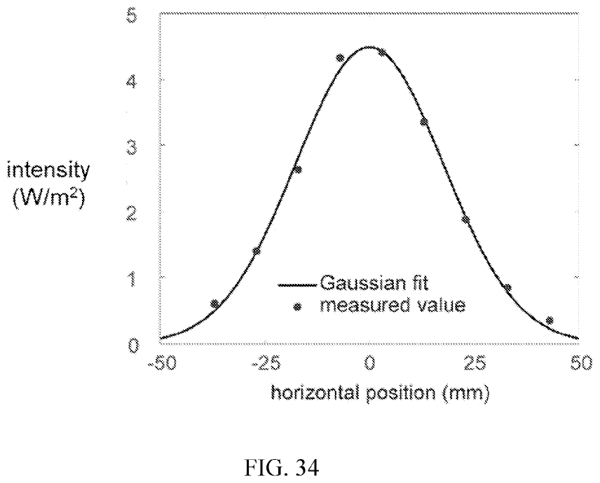

For measurements at (i) and (ii), a 60-μm-diameter pinhole was mounted onto the photodetector. Then, the photodetector was translated along the horizontal diameter of the metalens while recording the received power and corresponding position. Using the obtained result, a 1-D gaussian fit of the beam's intensity profile was obtained, as shown in FIG. 34. Assuming rotational symmetry, the intensity distribution of the corresponding 2-D Gaussian beam could be calculated and the power incident on the metalens (at position (i)) and the transmitted power after the metalens (at position (ii)) could be obtained.

For measurements at (iii), a variable diameter iris was mounted onto the photodetector. The diameter of the iris is determined by calculating the numerical aperture of the metalens at the given wavelength and the distance between the iris and the photodetector's active region. Therefore, an iris diameter corresponding to an area with a diameter of 3-5 focal spot full-width-at-half-maxima (FWHMs) of the metalens focal spot could be calculated. In this manner, it can be ensured that light at the focal spot is completely captured while excluding the stray light and the background.

Using the abovementioned method, the total focusing efficiencies of the metalens at various wavelengths was calculated. At 1450 nm, the metalens achieved a peak efficiency of 80.84%. The transmittance of the metalens at this wavelength is calculated to be 91.11%.

### Strehl Ratio

The point spread function (PSF) of the metalens is measured at different wavelengths. Also, the focal lengths at these wavelengths are recorded, which can be used to calculate the actual NA of our metalens and obtain the corresponding diffraction-limited PSF. With this information, the Strehl ratio (SR) of the metalens could be calculated through the measured PSF.

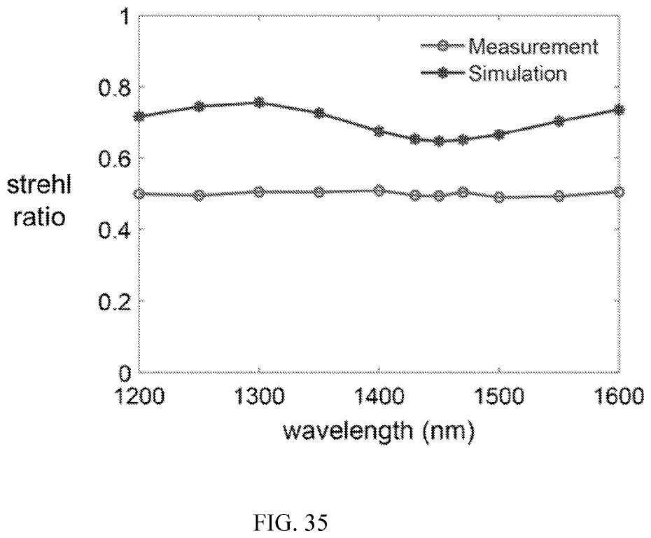

The SR is a criterion commonly used in optical industries to characterize the aberrations of the optical system. A value over 0.8 can be regarded as diffraction-limited level of performance. Following the calculation method stated in the main text, the SRs of the system were calculated as shown in FIG. 35. It can be seen that all results fall below 0.8, around a value of 0.5, indicating the performance of the system is not diffraction limited. However, multiple limiting factors from the instruments prevented a measured SR value above 0.8 even assuming the sample itself had diffraction-limited performance.

### MLCM

To validate the MLCM approach, several achromatic, polarization-independent MLCMs with up to 0.4-mm aperture sizes as well as 0.27 numerical apertures (NAs) were designed, fabricated, and characterized. Diffraction-limited focusing and imaging performance with Strehl ratios over 90% across the entire visible spectrum were observed. The MLCMs provide a focal length deviation across the visible band as small as 1.61% of the designed focal length. The best focusing efficiency was measured to be 88.12%. It is believed that the design approach provides a viable path toward realizing fast, large aperture and high-performance achromatic metalenses through the extension of GD range beyond what was possible previously, which will facilitate their application in practical optical devices.

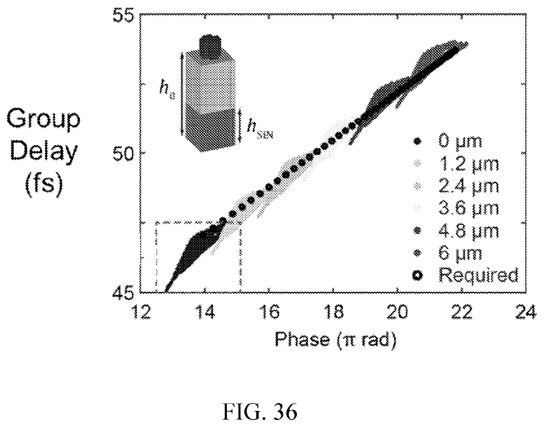

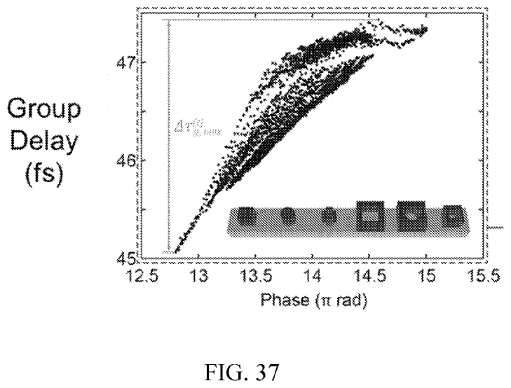

In the MLCMs, the top and bottom layers were designed as a whole instead of separately. The coupling between the two layers is automatically taken care of as the constituent meta-atoms include both components—the high-index SiN top nanoantenna and the low dispersion SiN bottom stair with the SU-8 spacer (FIG. 36, inset). The shapes of the nanoantennas fall into six types of shapes (FIG. 37, inset), which all possess C⁴ symmetry, rendering the design polarization-independent. The transmission phase and GD of each meta-atom were determined by combining full-wave simulations with the transfer-matrix (T-matrix) method. The transmission phase can be sampled at an arbitrary wavelength (700 nm in our case) in the band of interest, ∂φ/∂ω and is calculated as the amount of group delay. To calculate the group delay, the phase spectrum of all meta-atoms was approximated with least-square linear regression across the working bandwidth of 321.21 THz, from 400 nm to 700 nm. FIG. 37 shows the phase and GD from the top nanoantennas with a fixed bottom SiN stair thickness. Although a phase coverage of 2π is realized, the GD coverage is limited, which creates a bottleneck for achromatic metalens designs with large aperture size and high numerical aperture (NA). This constraint can be attributed to both the moderate height (600 nm) of SiN nanoantennas and the relatively low refractive index of the nanoantenna material compared to their near-infrared counterparts (e.g., silicon).

This issue was resolved by utilizing multiple thicknesses of the bottom SiN stairs, which effectively shifts the point cluster in the phase-GD diagram in both x- and y-directions. Since GD is linearly dependent on phase for an ideal achromatic lens with a slope of 1/ω, the point clusters are required to shift linearly with the same slope when varying the thickness of the bottom stairs, ideally.

From the calculations, it was observed that the additional group delay, denoted by τ_{(g)}^{(b)}, provided by the bottom SiN stair can remain invariant across the working band if there is a constant refractive index difference, Δn=n_{SiN}^{(b)}−n_{SU8}, between the bottom SiN stairs and SU-8.

The approximate expression for τ_{g}^{(b)} is given by

$${τ}_{g}^{( b )} \approx \frac{1}{c} ( {h}_{0} {n}_{SU 8} + {h}_{SiN} Δ n ) ,$$

where c is the speed of light in the vacuum, h₀ is the largest spacer layer thickness, h_{SiN} is the bottom SiN stair height, and n_{SiN}^{(b)} and n_{SU8} are the refractive indices of bottom SiN and SU-8, respectively. Therefore, by varying the height of the SiN stairs, the additional group delay can be modulated, which is much larger than that can be provided by the top nanoantennas but with larger granularity. Having a height varying interval for the bottom SiN stairs no greater than

$$Δ {h}_{SiN , max} \approx \frac{c {Δτ}_{g , max}^{( t )}}{{n}_{SiN}^{( b )} - {n}_{SU 8}}$$

allows the group delay coverage to expand multiple times without eliminating their overlapping regions (FIG. 36). Here, Δτ_{g,max}^{(t)} is the maximum GD range provided by the top nanoantennas.

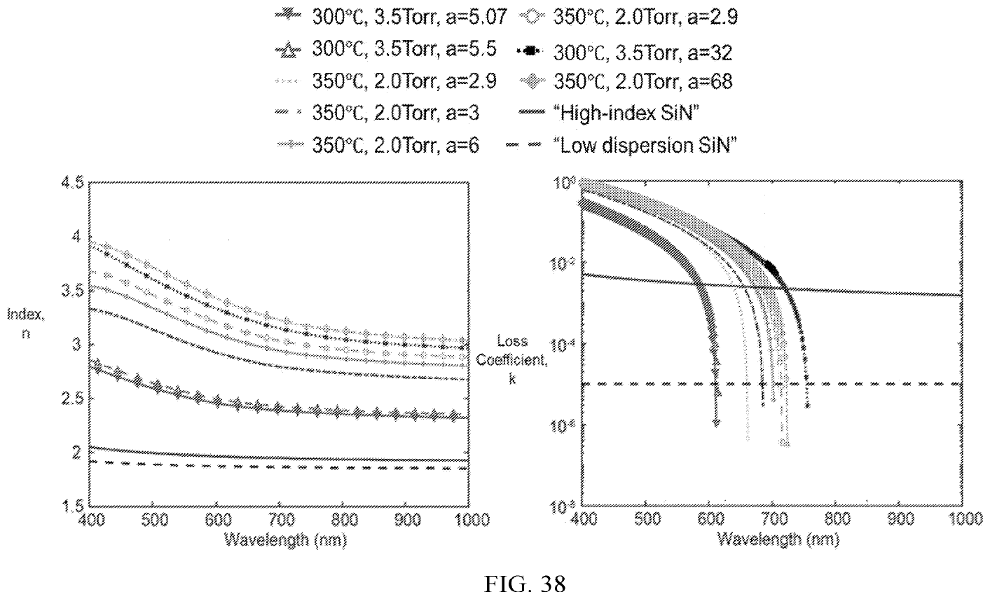

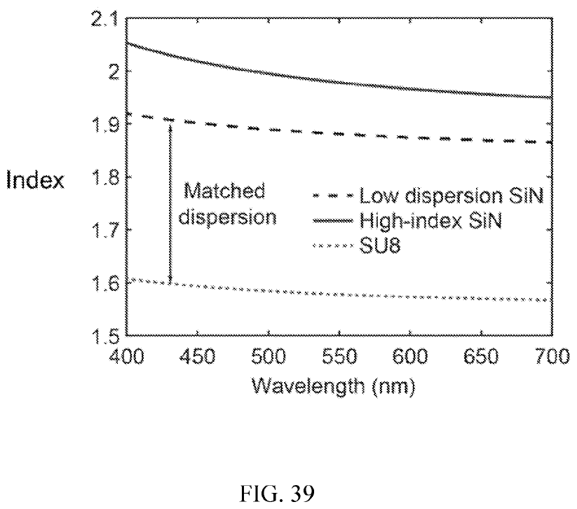

To fulfill the requirement described above, the material dispersion of the bottom stairs was engineered to maintain a constant refractive index difference between the spacer material. SiN was chosen as the material for the stairs due to its ability to be engineered through synthesis conditions and material composition. SiN films were synthesized with different conditions and compositions and their indices were characterized through ellipsometry measurements. This demonstrated a wide range of tunable indices and highly flexible dispersion curves for our SiN films (FIG. 38). Through this process, the dispersion of the SiN stairs across the band of interest was minimized, ensuring a nearly constant refractive index difference between the spacer material, SU-8 (FIG. 39). As a result, in the largest-aperture MLCM design, the GD range was extended by about six times (FIG. 36) compared to the contribution from nanoantennas alone.

In general, the required phase profile of a metalens at any arbitrary radial position r can be written as

$$φ ( r , ω ) = \frac{ω}{c} ( f - \sqrt{{f}^{2} + {r}^{2}} ) + {φ}_{0} ,$$

where f is the focal length and ω is the angular frequency. The required GD can be expressed as

$${τ}_{g} ( r ) = \frac{\partial φ ( r , ω )}{\partial ω} [ φ ( r , {ω}_{0} ) - {φ}_{0} ] ,$$

where φ(r, ω₀) is the required phase shift at an arbitrary reference angular frequency ω₀, and φ₀ is the phase shift at the reference frequency. This linear relationship has been utilized in designing achromatic metalenses in earlier studies and is illustrated by the black dotted line in FIG. 36, referred to as the “requirement line” thereafter.

By analyzing the overlap between the “requirement line” and the point clusters from the meta-atom library in the phase-GD plot (FIG. 36), the design limitations and capabilities of the existing meta-atom library for constructing MLCMs can be determined. Substantial overlap between the “requirement line” and the point clusters from the meta-atom library, as observed in FIG. 36, suggests the potential to achieve broad range group delay compensation, which is a crucial aspect in the design of broadband achromatic metalenses.

The straightforward presentation of the phase-GD plot may be tempting for many to design a metalens directly from it. However, the inevitable existence of resonances in the meta-atoms causes their phase response to deviate from linear phase dispersion, which renders the GD frequency-dependent. This means that the representation of a single GD value for each meta-atom design is not accurate.

To address the issue of frequency-dependence of GD, the average of GD across a specific frequency range Δω at each frequency of interest ω within the working band was investigated. This led the local average group delay (LAGD) for the meta-atoms to be defined:

$${τ}_{g , LA} ( ω ) = \frac{{\int }_{ω - \frac{Δω}{2}}^{ω + \frac{Δω}{2}} {τ}_{g} ( {ω}^{′} ) d {ω}^{′}}{Δω} = \frac{φ ( ω + \frac{Δω}{2} ) - φ ( ω - \frac{Δω}{2} )}{Δω}$$

This quantity provides additional flexibility in designing metalenses compared to GD. It accounts for the nonlinearity in the phase dispersion of the meta-atoms. In the case of a meta-atom that exhibits exactly linear phase dispersion, the LAGD simply reduces to the standard GD.

To reconcile the meta-atom's frequency-dependent LAGD with the required constant GD from the above equation, a frequency-dependent phase offset φ₀(ω) to all meta-atoms' phase spectra is introduced. Since φ₀(ω) acts as a constant phase shift on all meta-atoms at each frequency, it does not change the behavior of the metalens. This addition allows one to compensate meta-atoms' LAGDs if we choose φ₀(ω) appropriately so that

$${τ}_{g} ( r ) = {τ}_{g , LA} ( r , ω ) + \frac{\partial {φ}_{0} ( ω )}{\partial ω} .$$

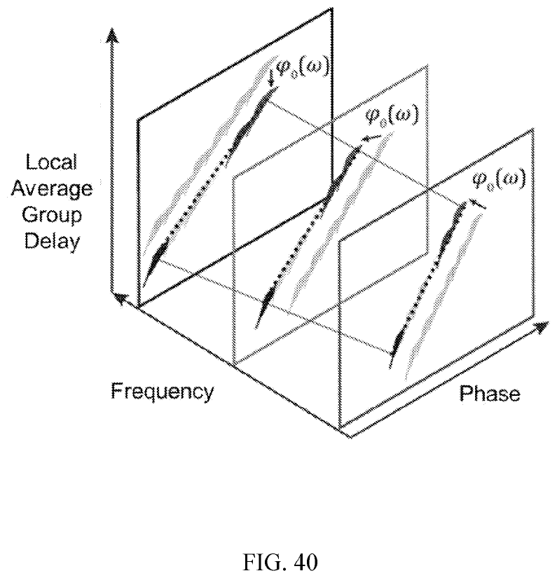

In FIG. 40, the effect of φ₀(ω) by displaying the phase-GD relationships at various frequencies is illustrated, as well as the phase-LAGD pairs of the meta-atoms at those frequencies. Without the addition of φ₀(ω), the phase-LAGD point clusters (of meta-atoms do not have a good overlap with the requirement lines (depicted as dotted lines) at all frequencies due to the nonlinearity in meta-atom phase dispersions. In contrast, after incorporating φ₀(ω), it alters both the phases and LAGDs of the meta-atoms, shifting the point clusters to achieve a much better overlap with the requirement lines at all frequencies. In practice, we used a global optimization process to find the optimal φ₀(ω).

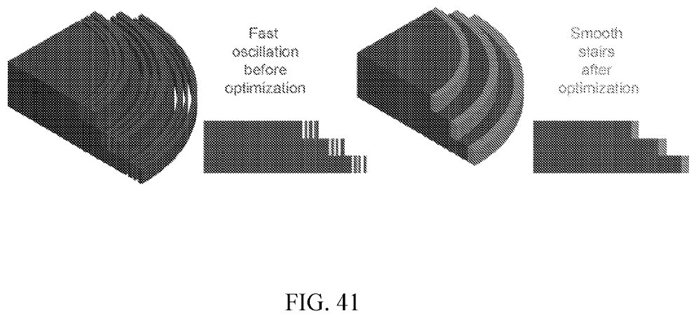

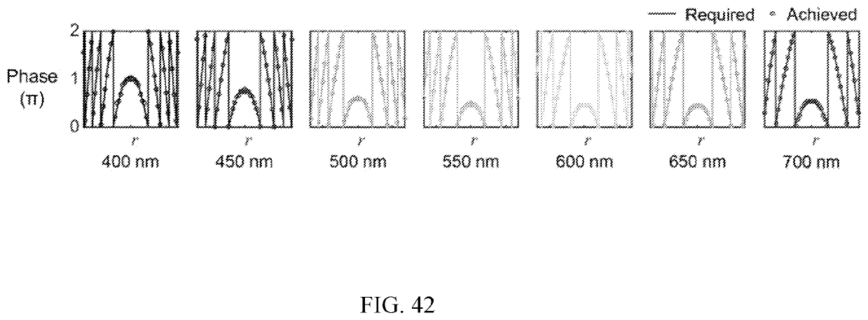

As for the MLCMs, the design process described above only considers the design that provides the best matching phase and GD, regardless of the monotonicity of the bottom-layer stair heights when the meta-atoms are assembled. As a result, there is a possibility that stair heights at neighboring sites will change in an oscillatory manner, which could lead to unnecessary fabrication challenges. This issue can be avoided if we also include the constraint of a smooth stair profile during the optimization. However, such a multi-objective optimization would take much more effort to find the optimal solution. Instead, a simple two-step strategy to guarantee a monotonic stair height variation was developed: First, a global optimization without stair height constraint is conducted to find the globally optimal layout; Second, a local optimization is used to fine-tune the stair heights, using the previous optimal solution as the initial condition. FIG. 41 illustrates the effect on stair height from this two-step optimization process. This strategy allows one to quickly reach the proximity of the actual optimal solution and enforce the stair height continuity constraint without significant performance deterioration and extended optimization time. FIG. 42 shows the required and realized phase profiles of our finalized MLCM design at seven sampling wavelengths, with minimal phase deviations.

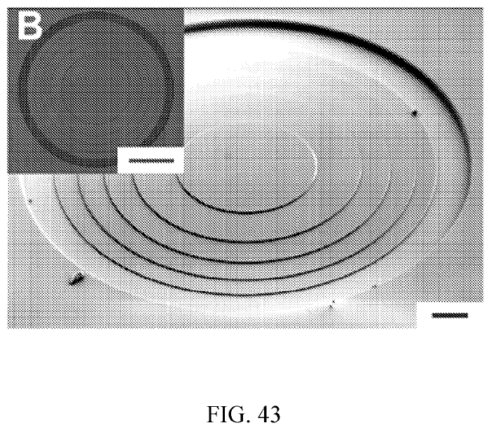

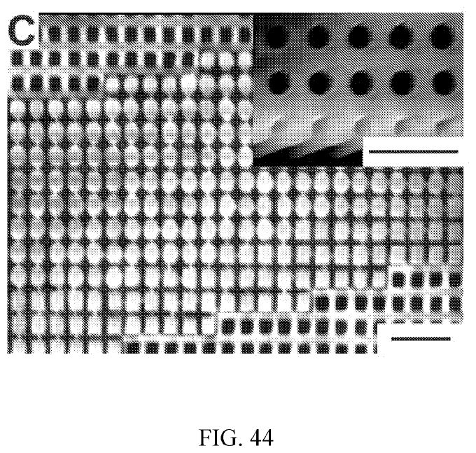

Utilizing the achromatic MLCM design strategy, a set of MLCMs with aperture sizes of 31 μm, 66 μm, 200 μm, and 400 μm, and NAs of 0.27, 0.11, 0.04, and 0.02, respectively, were designed. In the last two designs, six SiN stairs were used instead of four used in the first two designs, all with a 1.2 μm height interval. The bottom layers of the designed MLCMs were fabricated using photolithography processes and their top layers were fabricated using electron-beam lithography processes. The SEM images of the bottom SiN stairs (FIG. 43) and the top SiN nanoantennas (FIG. 44) show well-resolved patterns and great sidewall verticalness.

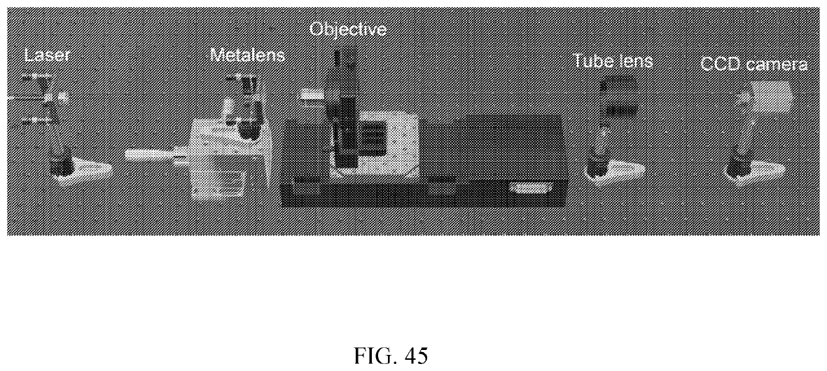

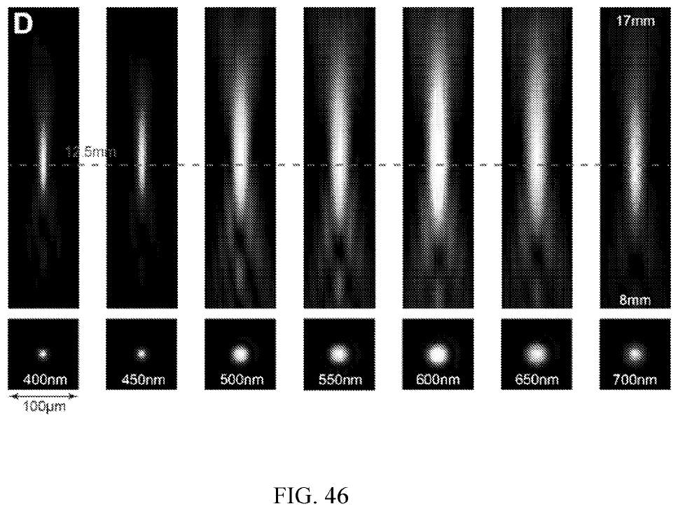

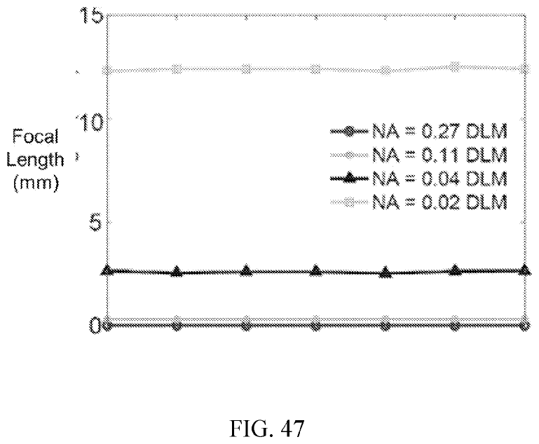

The focusing performance of our fabricated MLCMs was characterized using a typical microscope-type imaging system (FIG. 45). The light intensity distribution after the MLCM was captured by a 10× objective and a 200-mm-focal-length tube lens. FIG. 46 shows the measured transmitted light intensity distribution in both the longitudinal cross-section and the focal plane at seven wavelengths evenly distributed from 400 nm to 700 nm, for the 400-μm-aperture MLCM. A focal spot stable at 12.35 mm was observed, showing little variations of the focal lengths across the entire visible light spectrum, which matches well with our design (FIG. 46). Similarly, the focal length was also characterized for the other three fabricated MLCMs. The measured focal lengths for all four MLCMs show negligible variation across the entire visible light spectrum (FIG. 47).

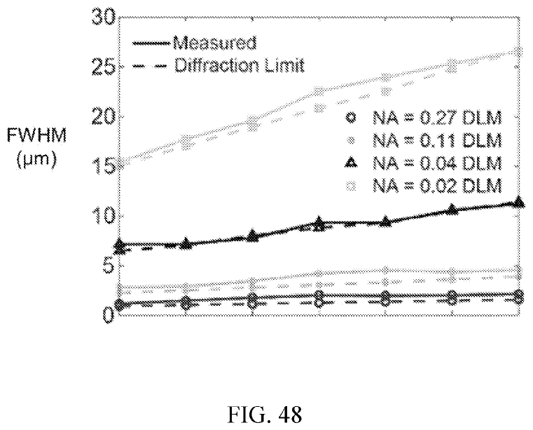

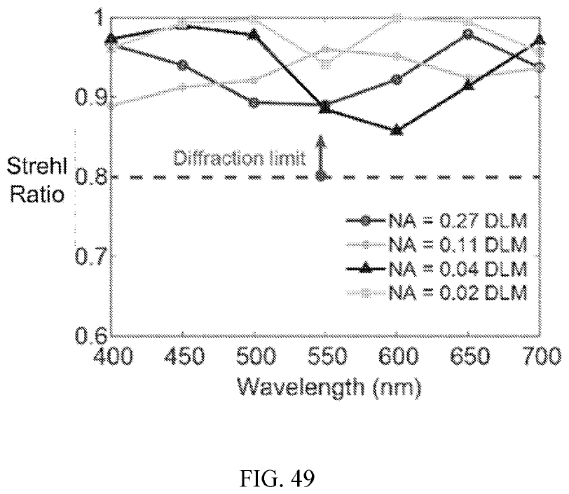

The resolution of an ideal imaging system is bounded by a fundamental limit known as the diffraction limit. The full-width-at-half-maximum (FWHM) of the focal spot at each wavelength for all MLCMs was measured and compared the results to the diffraction limit. As shown in FIG. 48, the measured spot sizes are very close to the diffraction limit, suggesting diffraction-limited performance. To quantitatively verify that, the Strehl ratio of our lenses at different wavelengths was also characterized, as shown in FIG. 49. The Strehl ratio is a quantity that characterizes the quality of the point spread function (PSF) formed by an imaging system. Any system that has a value of 0.8 or higher is usually considered to have diffraction-limited performance (33). The MLCMs achieved a Strehl ratio of 0.9 or higher at most of the wavelengths and exceeded 0.85 at all wavelengths.

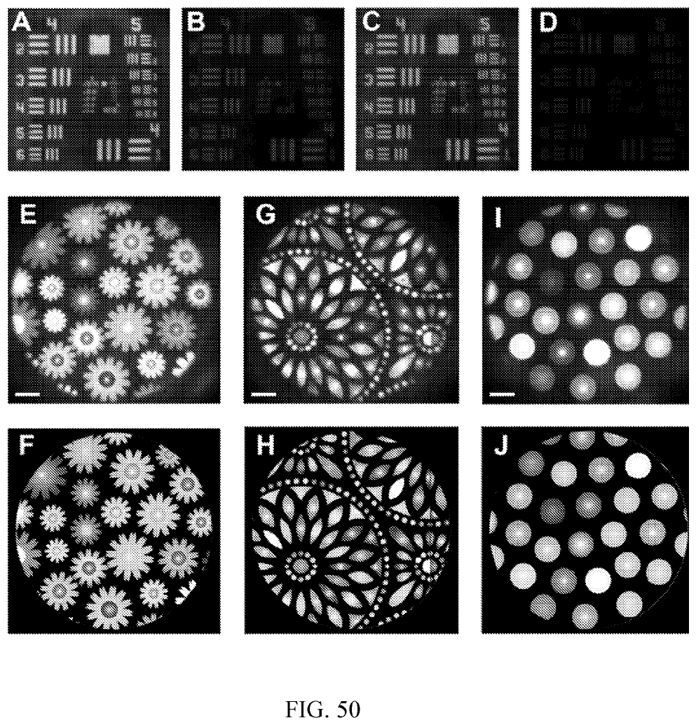

The MLCMs were tested with near-ideal PSFs to validate the promising imaging capabilities in various imaging scenarios. The results for the 400-μm aperture MLCM are presented in FIG. 50. FIG. 50 shows the USAF 1951 resolution test chart, imaged by the MLCM and captured with a color CCD camera (A), and red (B), green (C), and blue (D) channel images are extracted and shown. FIG. 50 further shows Images of different colorful pictures as target objects (E)-(J), and captured images: (E), (G), and (I); Original pictures: (F), (H), and (J). All scale bars: 200 μm.

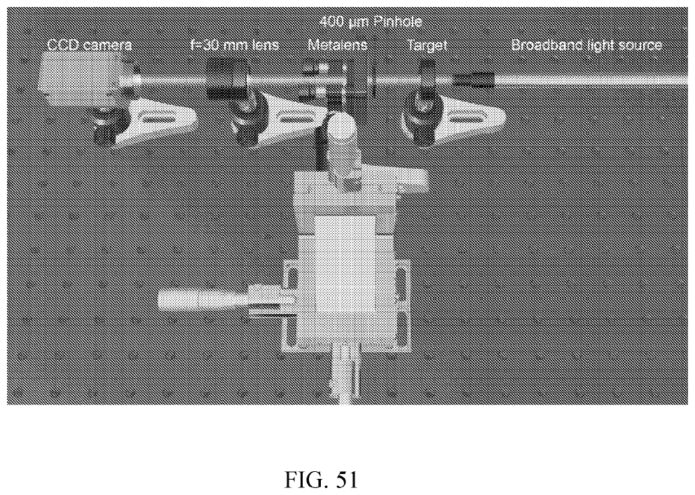

The test started with a standard 1951 USAF resolution test target as the object, which was illuminated by a collimated broadband light source. The MLCM was used as an objective lens, coupled with a 30 mm achromatic doublet lens to form a microscope system, and a color CCD was used to capture the image (FIG. 51). Since the substrate contains an array of multiple fabricated MLCMs, a 0.5-mm diameter pinhole was used to select one MLCM to test and blocked all others. The finest line group that the MLCM can resolve is Group 5 Element 6, which corresponds to a resolution of 57 lines pairs per mm (lp/mm), and a line width of 8.77 μm (FIG. 50), matching well with our focusing test results. FIG. 50 shows the separated RGB channels of the raw image captured by the color CCD, exhibiting a well-balanced spectral response.

Finally, the MLCMs were used to image full-color images. Three different color images (FIG. 50) were used as objects, which were displayed on a Full-HD liquid crystal display (LCD) and transferred to the object plane of the MLCM with an inverse microscope system with 15× size reduction. The obtained images are shown in FIG. 50. The colors and details of the target images are well-resolved by the MLCMs, and the colors were preserved with high fidelity, indicating achromatic performance across the visible light spectrum. The imperfect edges of the obtained images were caused by the pinhole we used to select the MLCM for the test. As the distance between the pinhole and the MLCM cannot be eliminated, it leads to a limited maximum chief ray angle (CRA) on the object side, causing vignetting of the images.

### Materials and Methods

### Numerical Simulation of Meta-Atoms

Full-wave simulation was combined with the T-matrix method to obtain the phase and GD responses of meta-atoms. First, all nanoantennas are simulated with periodic boundary conditions in a commercial finite element solver package—COMSOL. The complex Fresnel coefficients of reflection and transmission were retrieved from the model. Next, the nanoantennas were connected with the bottom SiN stair and SU-8 spacer. Here, the nanoantennas were considered as a film with known Fresnel coefficients. The transmission coefficients for the complete meta-atoms were calculated using:

$$[ \begin{matrix}{E}_{+ z} ( z = {z}_{0} ) \\ {E}_{- z} ( z = {z}_{0} )\end{matrix} ] = {M}_{SU 8 / nano} {M}_{SiN} [ \begin{matrix}{E}_{+ z} ( z = 0 ) \\ {E}_{- z} ( z = 0 )\end{matrix} ] .$$

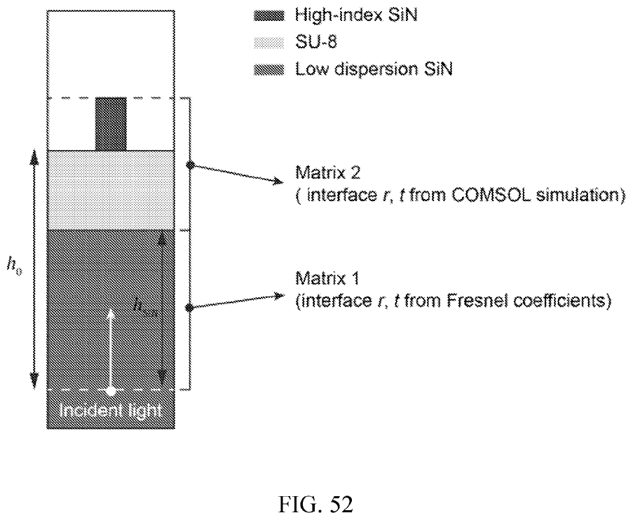

Here, E_{+z} and E_{-z} indicate the electric field of light propagating forward (+z) and backward (−z) along the axis z. The meta-atom structure starts at z=0 and ends at z=z₀. FIG. 52 illustrates the model configuration. The T-matrices for the nanoantenna layer and SiN layer were given as follows, respectively:

$${M}_{SU 8 / nano} = \frac{{t}_{SU 8 , NA}}{1 - {r}_{SU 8 , NA}^{2}} [ \begin{matrix}- {r}_{SU 8 , NA} & 1 \\ 1 & - {r}_{SU 8 , NA}\end{matrix} ] [ \begin{matrix}{e}^{{in}_{SU 8} {k}_{0} ( {h}_{0} - {h}_{SiN} )} & 0 \\ 0 & {e}^{- {in}_{SU 8} {k}_{0} ( {h}_{0} - {h}_{SiN} )}\end{matrix} ] ,$$

$${M}_{SiN} = \frac{{t}_{SiN , SU 8}}{1 - {r}_{SiN , SU 8}^{2}} [ \begin{matrix}- {r}_{SiN , SU 8} & 1 \\ 1 & - {r}_{SiN , SU 8}\end{matrix} ] [ \begin{matrix}{e}^{{in}_{SiN} {k}_{0} {h}_{SiN}} & 0 \\ 0 & {e}^{- {in}_{SiN} {k}_{0} {h}_{SiN}}\end{matrix} ] ,$$

where t_{a,b} and r_{a,b} are the complex Fresnel coefficients of reflection and transmission for light propagating from media a to b.

### Fabrication of the Achromatic MLCMs

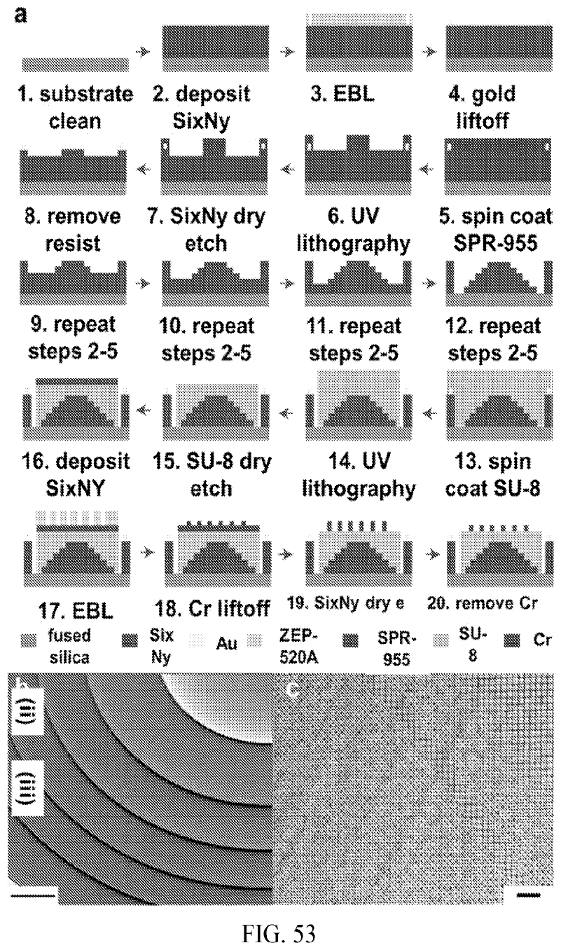

The MLCMs were fabricated on top of a fused silica substrate. First, a 6-μm low-dispersion SiN film was deposited using PECVD with the gas ratio NH₃:SiH₄=140:35. Following that, gold markers for the alignment of the bottom stairs layer and top nanoantenna layer were defined using E-beam lithography (EBPG Vistec 5200). Multiple contact lithography and ICP-RIE dry etching steps were used to define the bottom stairs. Next, SU8 was spin-coated to planarize the surface. The SU8 was back etched to decrease its thickness and then underwent thermal reflow at 220° C. to relocate and harden the material. For the final device layer, a 600 nm high-index SiN was grown by PECVD with a gas ratio NH₃:SiH₄=100:75. Finally, the top meta-atom layer was fabricated with e-beam lithography and ICP-RIE dry etching, where a 40-nm Cr layer was used as the etching mask. The fabrication process is shown in FIG. 53.

### Characterization Experiments of the Achromatic MLCMs

The characterization setup shown in FIG. 43 consists of an infinity-corrected objective lens with 0.25 NA and 10× magnification (0.6 NA and 50× magnification for characterizing the NA=0.27 MLCM) and a 2-inch wide-angle tube lens with a 200-mm focal length that matches the objective. The objective was mounted on a motorized translation stage to scan along the optical axis. A GigE monochromatic CCD camera was placed at the back-focal plane of the tube lens for image acquisition. The fabricated metalenses were positioned on a 3-D translation stage to align with the beam. For sample illumination, a tunable wavelength Ti: Sapphire laser was coupled into the system with a single-mode fiber. The output beam was then collimated and illuminated the sample from the backside.

The experimental setup for imaging is depicted in FIG. 51. A broadband light source was used to illuminate the USAF 1951 resolution test target. The metalens was mounted on a 3-D translation stage. To prevent light from entering nearby metalenses, as multiple metalenses were fabricated on the same chip, a 500-μm-diameter pinhole was placed right in front of the metalens. The light collected by the metalens continued to propagate through a conventional lens with a 30 mm focal length. The metalens and the second lens formed a microscope system for imaging. Finally, the image was captured by a color CCD camera.

### REFERENCES

[1] Loker, A. Profiles in Colonial History; Aleck Loker, 2008.
[2] Born, M.; Wolf, E. Principles of Optics: Electromagnetic Theory of Propagation, Interference and Diffraction of Light, 7th ed.; Cambridge University Press: Cambridge, 1999. https://doi.org/10.1017/CB09781139644181.
[3] Stone, T.; George, N. Hybrid Diffractive-Refractive Lenses and Achromats. Appl. Opt., AO 1988, 27 (14), 2960-2971. https://doi.org/10.1364/AO.27.002960.
[4] Buralli, D. A.; Rogers, J. R. Some Fundamental Limitations of Achromatic Holographic Systems. J Opt. Soc. Am. A, JOSAA 1989, 6 (12), 1863-1868. https://doi.org/10.1364/JOSAA.6.001863.
[5] Chang, S.; Guo, X.; Ni, X. Optical Metasurfaces: Progress and Applications. Annual Review of Materials Research 2018, 48 (1), 279-302. https://doi.org/10.1146/annurev-matsci-070616-124220.
[6] Kamali, S. M.; Arbabi, E.; Arbabi, A.; Faraon, A. A Review of Dielectric Optical Metasurfaces for Wavefront Control. Nanophotonics 2018, 7 (6), 1041-1068. https://doi.org/10.1515/nanoph-2017-0129.
[7] Yu, N.; Capasso, F. Flat Optics with Designer Metasurfaces. Nature Mater 2014, 13 (2), 139-150. https://doi.org/10.1038/nmat3839.
[8] Kildishev, A. V.; Boltasseva, A.; Shalaev, V. M. Planar Photonics with Metasurfaces. Science 2013, 339 (6125), 1232009-1232009. https://doi.org/10.1126/science.1232009.
[9] Chen, W. T.; Zhu, A. Y.; Sanjeev, V.; Khorasaninejad, M.; Shi, Z.; Lee, E.; Capasso, F. A Broadband Achromatic Metalens for Focusing and Imaging in the Visible. Nature Nanotech 2018, 13 (3), 220-226. https://doi.org/10.1038/s41565-017-0034-6.
[10] Wang, S.; Wu, P. C.; Su, V.-C.; Lai, Y.-C.; Chen, M.-K.; Kuo, H. Y.; Chen, B. H.; Chen, Y. H.; Huang, T.-T.; Wang, J.-H.; Lin, R.-M.; Kuan, C.-H.; Li, T.; Wang, Z.; Zhu, S.; Tsai, D. P. A Broadband Achromatic Metalens in the Visible. Nature Nanotech 2018, 13 (3), 227-232. https://doi.org/10.1038/s41565-017-0052-4.
[11] Yu, N.; Genevet, P.; Kats, M. A.; Aieta, F.; Tetienne, J.-P.; Capasso, F.; Gaburro, Z. Light Propagation with Phase Discontinuities: Generalized Laws of Reflection and Refraction. science 2011, 334 (6054), 333-337.
[12] Arbabi, E.; Arbabi, A.; Kamali, S. M.; Horie, Y.; Faraon, A. Controlling the Sign of Chromatic Dispersion in Diffractive Optics with Dielectric Metasurfaces. Optica, OPTICA 2017, 4 (6), 625-632. https://doi.org/10.1364/OPTICA.4.000625.
[13] Chen, W. T.; Zhu, A. Y.; Sisler, J.; Bharwani, Z.; Capasso, F. A Broadband Achromatic Polarization-Insensitive Metalens Consisting of Anisotropic Nanostructures. Nat Commun 2019, 10 (1), 355. https://doi.org/10.1038/s41467-019-08305-y.
[14] Yesilkoy, F.; Arvelo, E. R.; Jahani, Y.; Liu, M.; Tittl, A.; Cevher, V.; Kivshar, Y.; Altug, H. Ultrasensitive Hyperspectral Imaging and Biodetection Enabled by Dielectric Metasurfaces. Nat. Photonics 2019, 13 (6), 390-396. https://doi.org/10.1038/s41566-019-0394-6.
[15] Faraji-Dana, M.; Arbabi, E.; Kwon, H.; Kamali, S. M.; Arbabi, A.; Bartholomew, J. G.; Faraon, A. Hyperspectral Imager with Folded Metasurface Optics. ACS Photonics 2019, 6 (8), 2161-2167. https://doi.org/10.1021/acsphotonics.9b00744.
[16] Chen, M. K.; Wu, Y.; Feng, L.; Fan, Q.; Lu, M.; Xu, T.; Tsai, D. P. Principles, Functions, and Applications of Optical Meta-Lens. Advanced Optical Materials 2021, 9 (4), 2001414. https://doi.org/10.1002/adom.202001414.
[17] Su, V.-C.; Chu, C. H.; Sun, G.; Tsai, D. P. Advances in Optical Metasurfaces: Fabrication and Applications [Invited]. Opt. Express, OE 2018, 26 (10), 13148-13182. https://doi.org/10.1364/OE.26.013148.
[18] Baracu, A. M.; Avram, M. A.; Breazu, C.; Bunea, M.-C.; Socol, M.; Stanculescu, A.; Matei, E.; Thrane, P. C. V.; Dirdal, C. A.; Dinescu, A.; Rasoga, O. Silicon Metalens Fabrication from Electron Beam to UV-Nanoimprint Lithography. Nanomaterials 2021, 11 (9), 2329. https://doi.org/10.3390/nano11092329.
[19] Luo, X.; Zhang, F.; Pu, M.; Guo, Y.; Li, X.; Ma, X. Recent Advances of Wide-Angle Metalenses: Principle, Design, and Applications. Nanophotonics 2022, 11 (1), 1-20. https://doi.org/10.1515/nanoph-2021-0583.
[20] Song, W.; Liang, X.; Li, S.; Li, D.; Paniagua-Dominguez, R.; Lai, K. H.; Lin, Q.; Zheng, Y.; Kuznetsov, A. I. Large-Scale Huygens' Metasurfaces for Holographic 3D Near-Eye Displays. Laser & Photonics Reviews 2021, 15 (9), 2000538. https://doi.org/10.1002/lpor.202000538.
[21] Byrnes, S. J.; Lenef, A.; Aieta, F.; Capasso, F. Designing Large, High-Efficiency, High-Numerical-Aperture, Transmissive Meta-Lenses for Visible Light. Opt. Express, OE 2016, 24 (5), 5110-5124. https://doi.org/10.1364/OE.24.005110.
[22] Zou, X.; Zheng, G.; Yuan, Q.; Zang, W.; Chen, R.; Li, T.; Li, L.; Wang, S.; Wang, Z.; Zhu, S. Imaging Based on Metalenses. PhotoniX 2020, 1 (1), 2. https://doi. org/10.1186/s43074-020-00007-9.
[23] Moon, S.-W.; Kim, Y.; Yoon, G.; Rho, J. Recent Progress on Ultrathin Metalenses for Flat Optics. iScience 2020, 23 (12), 101877. https://doi.org/10.1016/j.isci.2020.101877.
[24] Phan, T.; Sell, D.; Wang, E. W.; Doshay, S.; Edee, K.; Yang, J.; Fan, J. A. High-Efficiency, Large-Area, Topology-Optimized Metasurfaces. Light Sci Appl 2019, 8 (1), 48. https://doi.org/10.1038/s41377-019-0159-5.
[25] Zhao, F.; Zhao, F.; Shen, Z.; Wang, D.; Xu, B.; Chen, X.; Chen, X.; Yang, Y.; Yang, Y. Synthetic Aperture Metalens. Photon. Res., PRJ 2021, 9 (12), 2388-2397. https://doi.org/10.1364/PRJ.440185.
[26] Brièré, G.; Ni, P.; Héron, S.; Chenot, S.; Vezian, S.; Brandli, V.; Damilano, B.; Duboz, J.-Y.; Iwanaga, M.; Genevet, P. An Etching-Free Approach Toward Large-Scale Light-Emitting Metasurfaces. Advanced Optical Materials 2019, 7 (14), 1801271. https://doi.org/10.1002/adom.201801271.
[27] Li, N.; Xu, Z.; Dong, Y.; Hu, T.; Zhong, Q.; Fu, Y. H.; Zhu, S.; Singh, N. Large-Area Metasurface on CMOS-Compatible Fabrication Platform: Driving Flat Optics from Lab to Fab. Nanophotonics 2020, 9 (10), 3071-3087. https://doi.org/10.1515/nanoph-2020-0063.
[28] Ni, H.; Yuan, G.; Sun, L.; Chang, N.; Zhang, D.; Chen, R.; Jiang, L.; Chen, H.; Gu, Z.; Zhao, X. Large-Scale High-Numerical-Aperture Super-Oscillatory Lens Fabricated by Direct Laser Writing Lithography. RSC Advances 2018, 8 (36), 20117-20123. https://doi.org/i0.1039/C8RA02644K.
[29] Park, J.-S.; Zhang, S.; She, A.; Chen, W. T.; Lin, P.; Yousef, K. M. A.; Cheng, J.-X.; Capasso, F. All-Glass, Large Metalens at Visible Wavelength Using Deep-Ultraviolet Projection Lithography. Nano Lett. 2019, 19 (12), 8673-8682. https://doi.org/10.1021/acs.nanolett.9b03333.
[30] Hu, T.; Zhong, Q.; Li, N.; Dong, Y.; Xu, Z.; Fu, Y. H.; Li, D.; Bliznetsov, V.; Zhou, Y.; Lai, K. H.; Lin, Q.; Zhu, S.; Singh, N. CMOS-Compatible a-Si Metalenses on a 12-Inch Glass Wafer for Fingerprint Imaging. Nanophotonics 2020, 9 (4), 823-830. https://doi.org/10.1515/nanoph-2019-0470.
[31] Mahajan, V. N. Optical Imaging and Aberrations; SPIE: 1000 20th Street, Bellingham, WA 98227-0010 USA, 2001. https://doi.org/10.1117/3.415727.
[32] Khorasaninejad, M.; Zhu, A. Y.; Roques-Carmes, C.; Chen, W. T.; Oh, J.; Mishra, I.; Devlin, R. C.; Capasso, F. Polarization-Insensitive Metalenses at Visible Wavelengths. Nano Lett. 2016, 16 (11), 7229-7234. https://doi.org/10.1021/acs.nanolett.6b03626.
[33] Li, Z.; Lin, P.; Huang, Y.-W.; Park, J.-S.; Chen, W. T.; Shi, Z.; Qiu, C.-W.; Cheng, J.-X.; Capasso, F. Meta-Optics Achieves RGB-Achromatic Focusing for Virtual Reality. Science Advances 2021, 7 (5), eabe4458. https://doi.org/10.1126/sciadv.abe4458.
[34] X. Ni, S. Ishii, A. V. Kildishev, V. M. Shalaev, Ultra-thin, planar, Babinet-inverted plasmonic metalenses. Light: Science & Applications. 2, e72 (2013).
[35] A. Pors, M. G. Nielsen, R. L. Eriksen, S. I. Bozhevolnyi, Broadband Focusing Flat Mirrors Based on Plasmonic Gradient Metasurfaces. Nano Lett. 13, 829-834 (2013).
[36] M. Khorasaninejad, W. T. Chen, R. C. Devlin, J. Oh, A. Y. Zhu, F. Capasso, Metalenses at visible wavelengths: Diffraction-limited focusing and subwavelength resolution imaging. Science. 352, 1190-1194 (2016).
[37] F. Aieta, P. Genevet, M. Kats, F. Capasso, Aberrations of flat lenses and aplanatic metasurfaces. Opt. Express, OE. 21, 31530-31539 (2013).
[38] M. Khorasaninejad, F. Capasso, Metalenses: Versatile multifunctional photonic components. Science, eaam8100 (2017).
[39] P. Lalanne, P. Chavel, Metalenses at visible wavelengths: past, present, perspectives. Laser & Photonics Reviews. 11 (2017) (available at http://onlinelibrary.wiley.com/doi/10.1002/lpor.201600295/full).
[40] S. Chang, X. Guo, X. Ni, Optical Metasurfaces: Progress and Applications. Annual Review of Materials Research. 48, 279-302 (2018).
[41] W. T. Chen, A. Y. Zhu, V. Sanjeev, M. Khorasaninejad, Z. Shi, E. Lee, F. Capasso, A broadband achromatic metalens for focusing and imaging in the visible. Nature Nanotech. 13, 220-226 (2018).
[42] Z. Li, P. Lin, Y.-W. Huang, J.-S. Park, W. T. Chen, Z. Shi, C.-W. Qiu, J.-X. Cheng, F. Capasso, Meta-optics achieves RGB-achromatic focusing for virtual reality. Science Advances. 7, eabe4458 (2021).
[43] S. J. Byrnes, A. Lenef, F. Aieta, F. Capasso, Designing large, high-efficiency, high-numerical-aperture, transmissive meta-lenses for visible light. Opt. Express, OE. 24, 5110-5124 (2016).
[44] S. Shrestha, A. C. Overvig, M. Lu, A. Stein, N. Yu, Broadband achromatic dielectric metalenses. Light: Science & Applications. 7, 85 (2018).
[45] A. Ndao, L. Hsu, J. Ha, J.-H. Park, C. Chang-Hasnain, B. Kanté, Octave bandwidth photonic fishnet-achromatic-metalens. Nat Commun. 11, 3205 (2020).
[46] F. Aieta, M. A. Kats, P. Genevet, F. Capasso, Multiwavelength achromatic metasurfaces by dispersive phase compensation. Science. 347, 1342-1345 (2015).
[47] M. Khorasaninejad, Z. Shi, A. Y. Zhu, W. T. Chen, V. Sanjeev, A. Zaidi, F. Capasso, Achromatic Metalens over 60 nm Bandwidth in the Visible and Metalens with Reverse Chromatic Dispersion. Nano Lett. 17, 1819-1824 (2017).
[48] Z.-B. Fan, H.-Y. Qiu, H.-L. Zhang, X.-N. Pang, L.-D. Zhou, L. Liu, H. Ren, Q.-H. Wang, J.-W. Dong, A broadband achromatic metalens array for integral imaging in the visible. Light Sci Appl. 8, 67 (2019).
[49] S. Wang, P. C. Wu, V.-C. Su, Y.-C. Lai, C. H. Chu, J.-W. Chen, S.-H. Lu, J. Chen, B. Xu, C.-H. Kuan, T. Li, S. Zhu, D. P. Tsai, Broadband achromatic optical metasurface devices. Nature Communications. 8, 187 (2017).
[50] S. Wang, P. C. Wu, V.-C. Su, Y.-C. Lai, M.-K. Chen, H. Y. Kuo, B. H. Chen, Y. H. Chen, T.-T. Huang, J.-H. Wang, R.-M. Lin, C.-H. Kuan, T. Li, Z. Wang, S. Zhu, D. P. Tsai, A broadband achromatic metalens in the visible. Nature Nanotechnology, 1 (2018).
[51] Y. Wang, Q. Chen, W. Yang, Z. Ji, L. Jin, X. Ma, Q. Song, A. Boltasseva, J. Han, V. M. Shalaev, S. Xiao, High-efficiency broadband achromatic metalens for near-IR biological imaging window. Nat Commun. 12, 5560 (2021).
[52] S. W. D. Lim, M. L. Meretska, F. Capasso, A High Aspect Ratio Inverse-Designed Holey Metalens. Nano Lett. 21, 8642-8649 (2021).
[53] W. T. Chen, A. Y. Zhu, J. Sisler, Z. Bharwani, F. Capasso, A broadband achromatic polarization-insensitive metalens consisting of anisotropic nanostructures. Nat Commun. 10, 355 (2019).
[54] X. Zhang, H. Huang, X. Guo, X. Zhang, Y. Duan, X. Chen, S. Chang, Y. Ding, X. Ni, Broadband Polarization-Independent Achromatic Metalenses with Unintuitively-Designed Random-Shaped Meta-Atoms. arXiiv:2103.10845 [physics] (2021) (available at http://arxiv.org/abs/2103.10845).
[55] H. Chung, H. Chung, O. D. Miller, O. D. Miller, High-NA achromatic metalenses by inverse design. Opt. Express, O. 28, 6945-6965 (2020).
[56] Z. Lin, S. G. Johnson, Overlapping domains for topology optimization of large-area metasurfaces. Opt. Express, OE. 27, 32445-32453 (2019).
[57] Z. Lin, V. Liu, R. Pestourie, S. G. Johnson, Topology optimization of freeform large-area metasurfaces. Opt. Express, OE. 27, 15765-15775 (2019).
[58] O. Avayu, E. Almeida, Y. Prior, T. Ellenbogen, Composite functional metasurfaces for multispectral achromatic optics. Nat Commun. 8, 14992 (2017).
[59] Y. Zhou, I. I. Kravchenko, H. Wang, J. R. Nolen, G. Gu, J. Valentine, Multilayer Noninteracting Dielectric Metasurfaces for Multiwavelength Metaoptics. Nano Lett. 18, 7529-7537 (2018).
[60] W. Feng, J. Zhang, Q. Wu, A. Martins, Q. Sun, Z. Liu, Y. Long, E. R. Martins, J. Li, H. Liang, RGB Achromatic Metalens Doublet for Digital Imaging. Nano Lett. (2022), doi:10.1021/acs.nanolett.2c00486.
[61] M. Li, S. Li, L. K. Chin, L. K. Chin, Y. Yu, Y. Yu, D. P. Tsai, R. Chen, R. Chen, Dual-layer achromatic metalens design with an effective Abbe number. Opt. Express, OE. 28, 26041-26055 (2020).
[62] F. Balli, M. Sultan, S. K. Lami, J. T. Hastings, A hybrid achromatic metalens. Nat Commun. 11, 3892 (2020).
[63] S. V. Nguyen, S. Fridmann, Plasma Deposition and Characterization of Thin Silicon-Rich Silicon Nitride Films. J. Electrochem. Soc. 134, 2324 (1987).
[64] D. K. T. Ng, Q. Wang, T. Wang, S.-K. Ng, Y.-T. Toh, K.-P. Lim, Y. Yang, D. T. H. Tan, Exploring High Refractive Index Silicon-Rich Nitride Films by Low-Temperature Inductively Coupled Plasma Chemical Vapor Deposition and Applications for Integrated Waveguides. ACS Appl. Mater. Interfaces. 7, 21884-21889 (2015).
[65] M. Ye, Y. Peng, Y. S. Yi, Silicon-rich silicon nitride thin films for subwavelength grating metalens. Opt. Mater. Express, OME. 9, 1200-1207 (2019).
[66] C. S. Williams, O. A. Becklund, Introduction to the Optical Transfer Function (SPIE Press, 2002).
[67] F. Presutti, F. Monticone, Focusing on bandwidth: achromatic metalens limits. Optica, OPTICA. 7, 624-631 (2020).

It should be understood that modifications to the embodiments disclosed herein can be made to meet a particular set of design criteria. For instance, the number of or configuration of components or parameters may be used to meet a particular objective.

It will be apparent to those skilled in the art that numerous modifications and variations of the described examples and embodiments are possible in light of the above teachings of the disclosure. The disclosed examples and embodiments are presented for purposes of illustration only. Other alternative embodiments may include some or all of the features of the various embodiments disclosed herein. For instance, it is contemplated that a particular feature described, either individually or as part of an embodiment, can be combined with other individually described features, or parts of other embodiments. The elements and acts of the various embodiments described herein can therefore be combined to provide further embodiments.

It is the intent to cover all such modifications and alternative embodiments as may come within the true scope of this invention, which is to be given the full breadth thereof. Additionally, the disclosure of a range of values is a disclosure of every numerical value within that range, including the end points. Thus, while certain exemplary embodiments of the device and methods of making and using the same have been discussed and illustrated herein, it is to be distinctly understood that the invention is not limited thereto but may be otherwise variously embodied and practiced within the scope of the following claims.

1. A metalens, comprising:
a plurality of nanocylinders spatially arranged on a substrate,
wherein the plurality of nanocylinders provide the metalens with an aperture having a diameter of 80 mm or less.

2. The metalens of claim 1, wherein the nanocylinders have a diameter between 240 nm and 520 nm.

3. The metalens of claim 2, wherein the nanocylinders have a diameter between 240 nm and 520 nm, excluding a diameter of 400 nm.

4. The metalens of claim 1, wherein the nanocylinders comprise amorphous silicon.

5. The metalens of claim 1, wherein the substrate comprises silica.

6. The metalens of claim 1, wherein the metalens is configured to operate in a near infrared region.

7. (canceled)

8. The metalens of claim 1, wherein the metalens has a transmittance greater than 95%.

9. The metalens of claim 1, wherein the metalens is included in a telescope.

10. A method to manufacture a metalens, comprising:
depositing a film on a substrate to provide an intermediate substrate;
projecting a light pattern through a photomask and a projection lens to a first quadrant of the intermediate substrate;
rotating the photomask or the intermediate substrate in 90-degree increments such that the light pattern is projected to a second quadrant of the intermediate substrate, a third quadrant of the intermediate substrate, and a fourth quadrant of the intermediate substrate;
baking the intermediate substrate; and
etching the film according to the light pattern to provide a plurality of nanocylinders.

11. The method according to claim 10, wherein the film is amorphous silicon.

12. (canceled)

13. The method according to claim 10, wherein the light pattern has a wavelength of 248 nm.

14. The method according to claim 10, wherein the projection lens has a four-to-one reduction ratio.

15. The method according to claim 10, wherein depositing the film on the substrate to provide the intermediate substrate comprises a plasma-enhanced chemical vapor deposition.

16. The method according to claim 10, wherein etching the film according to the light pattern to provide the plurality of nanocylinders comprises an inductively coupled plasma reactive ion etching process.

17. The method according to claim 10, further comprising:
coating the film with an anti-reflective coating after depositing the film on the substrate to provide the intermediate substrate.

18. The method according to claim 10, further comprising:
coating the film with a photoresist after depositing the film on the substrate to provide the intermediate substrate.

19. A metalens, comprising:
a substrate;
a first film deposited on top of the substrate, wherein the first film comprises a plurality of stairs;
a spacer layer coated on top of the first film layer and the substrate, wherein the spacer layer completely submerges the first film layer; and
a plurality of nanocylinders spatially arranged on top of the spacer layer.

20-24. (canceled)

25. The metalens of claim 19, wherein the metalens is configured to achieve achromatic focusing and imaging across the entire visible light spectrum.

26. The metalens of claim 19, wherein the metalens is configured to achieve an imaging performance with Strehl ratios over 90% across the entire visible spectrum.

27. (canceled)

28. The metalens of claim 19, wherein the spacer layer has a planar top surface.

29. The metalens of claim 19, wherein the metalens is included in a telescope.

30. A method to manufacture a metalens, comprising:
depositing a first film on a substrate, wherein the first film comprises a plurality of stairs;
coating a spacer layer on top of the first film layer and the substrate, wherein the spacer layer completely submerges the first film;
depositing a second film on the spacer layer; and
etching the second film to provide a plurality of nanocylinders.

31-33. (canceled)

34. The method according to claim 30, depositing the first film on the substrate comprises a plasma-enhanced chemical vapor deposition.

35. The method according to claim 30, etching the second film a to provide the plurality of nanocylinders comprises an inductively coupled plasma reactive ion etching process.

36. The method according to claim 30, wherein the spacer layer is etched to form a planar top surface after the spacer layer is coated on top of the first film layer and the substrate.
